(19) United States
(12) Patent Application Publication
(10) Pub. No.: US 2025/0212476 A1
(43) Pub. Date: Jun. 26, 2025

(54) METHOD AND SYSTEM FOR PLANARIZATION OF ENGINEERED SUBSTRATES

(71) Applicant: QROMIS, Inc., Santa Clara, CA (US)

(72) Inventors: Vladimir Odnoblyudov, Danville, CA (US); Cem Basceri, Los Gatos, CA (US); Casey Kurth, Boise, ID (US)

(73) Assignee: QROMIS, Inc., Santa Clara, CA (US)

(21) Appl. No.: 18/991,021

(22) Filed: Dec. 20, 2024

Related U.S. Application Data
(60) Provisional application No. 63/614,852, filed on Dec. 26, 2023.
(60) Provisional application No. 63/667,039, filed on Jul. 2, 2024.

(51) Int. Cl. H10D 62/85; H01L 21/02

(52) U.S. Cl. CPC H10D 62/8503; H01L 21/0254

(57) ABSTRACT

An engineered substrate includes a polycrystalline ceramic core, a first adhesion layer coupled to the polycrystalline ceramic core, a conductive layer coupled to the first adhesion layer, a second adhesion layer coupled to the conductive layer, a diffusion barrier layer coupled to the second adhesion layer, and a bonding layer coupled to the diffusion barrier layer. The engineered substrate also includes a substantially single crystal layer coupled to the bonding layer. A first region of the engineered substrate includes an epitaxial III-V layer coupled to the substantially single crystal layer. A second region of the engineered substrate includes a eutectic barrier layer coupled to the bonding layer, a planarization layer coupled to the eutectic barrier layer, and an epitaxial III-V layer coupled to the planarization layer.

### CROSS-REFERENCES TO RELATED APPLICATIONS

This application claims priority to U.S. Provisional Patent Application No. 63/614,852, filed on Dec. 26, 2023 and U.S. Provisional Patent Application No. 63/667,039, filed on Jul. 2, 2024, the disclosures of which are hereby incorporated by reference in their entireties for all purposes.

### BACKGROUND OF THE INVENTION

Gallium nitride-based device structures, including light-emitting diode (LED) structures are typically epitaxially grown on sapphire substrates. Many products currently use LED devices, including lighting, computer monitors, and other display devices. Additionally, gallium nitride-based power electronics are being developed for a wide variety of applications, including electric vehicles and battery systems.

Despite the progress made in the area of gallium-nitride-based device structures, there is a need in the art for improved methods and systems related to epitaxial growth processes and substrate structures.

### SUMMARY OF THE INVENTION

Embodiments of the present invention relate to semiconductor devices. More particularly, embodiments utilize a eutectic barrier layer included in the engineered substrates. The eutectic barrier layer prevents migration of a binding agent, for example, yttrium, yttrium oxide, and/or yttrium-based compounds from the polycrystalline ceramic core to adjacent engineered layers. In the embodiments discussed herein, yttria is discussed as a binding agent, but the present invention is not limited to this particular binding agent and other binding agents are included within the scope of the present invention. Embodiments of the present invention are applicable to engineered substrates useful in a variety of semiconductor device designs, including light emitting devices, power transistors, and the like.

Embodiments of the present invention also relate to semiconductor devices. More particularly, embodiments utilize a eutectic barrier layer formed on a single crystal layer included in the engineered substrates. The eutectic barrier layer formed on the single crystal layer seals one or all defects in the engineered substrates to prevent interaction between the single crystal layer and the device layers coupled to the single crystal layer that would otherwise lead to undesirable eutectic growth on the engineered substrates. Embodiments of the present invention are applicable to engineered substrates useful in a variety of semiconductor device designs, including light emitting devices, power transistors, and the like.

Numerous benefits are achieved by way of the present invention over conventional techniques. For example, embodiments of the present invention provide engineered substrates that include a eutectic barrier layer. The eutectic barrier layer prevents binding agents, for example, yttria and yttrium present in the polycrystalline ceramic core from migrating through the ceramic layer to adjacent engineered layers at elevated temperatures. Additionally, and for example, embodiments of the present invention provide engineered substrates that include a eutectic barrier layer formed on the single crystal layer. The eutectic barrier layer formed on the single crystal layer seals defects in the engineered substrates and prevents interaction between the single crystal layer and the device layers coupled to the single crystal layer that would otherwise lead to undesirable eutectic growth on the engineered substrates. These and other embodiments of the invention, along with many of its advantages and features, are described in more detail in conjunction with the text below and attached figures.

### BRIEF DESCRIPTION OF THE DRAWINGS

FIG. 1 is a simplified schematic diagram illustrating an engineered substrate structure.

FIG. 2A is a secondary ion mass spectroscopy (SIMS) profile illustrating species concentration (as-deposited) as a function of depth for an engineered structure according to an embodiment of the present invention.

FIG. 2B is a SIMS profile illustrating species concentration (after anneal) as a function of depth for an engineered structure without a diffusion barrier layer according to an embodiment of the present invention.

FIG. 2C is a SIMS profile illustrating species concentration (after anneal) as a function of depth for an engineered structure with a diffusion barrier layer according to an embodiment of the present invention.

FIG. 3 is a simplified schematic diagram illustrating a semiconductor device with yttrium-based compound migration according to an embodiment of the present invention.

FIG. 4A is a simplified schematic diagram illustrating an engineered substrate structure according to an embodiment of the present invention.

FIG. 4B is a simplified schematic diagram illustrating an engineered substrate structure according to another embodiment of the present invention.

FIG. 4C is a simplified schematic diagram illustrating an engineered substrate structure according to another embodiment of the present invention.

FIG. 4D is a simplified schematic diagram illustrating an engineered substrate structure according to another embodiment of the present invention.

FIG. 5A is a simplified schematic diagram illustrating an engineered substrate structure according to an embodiment of the present invention.

FIG. 5B is a simplified schematic diagram illustrating an engineered substrate structure according to another embodiment of the present invention.

FIG. 5C is a simplified schematic diagram illustrating an engineered substrate structure according to another embodiment of the present invention.

FIG. 5D is a simplified schematic diagram illustrating an engineered substrate structure according to another embodiment of the present invention.

FIG. 6A is a simplified schematic diagram illustrating an engineered substrate structure according to an embodiment of the present invention.

FIG. 6B is a simplified schematic diagram illustrating an engineered substrate structure according to another embodiment of the present invention.

FIG. 6C is a simplified schematic diagram illustrating an engineered substrate structure according to another embodiment of the present invention.

FIG. 6D is a simplified schematic diagram illustrating an engineered substrate structure according to another embodiment of the present invention.

FIG. 7A is a simplified schematic diagram illustrating an engineered substrate structure according to an embodiment of the present invention.

FIG. 7B is a simplified schematic diagram illustrating an engineered substrate structure according to another embodiment of the present invention.

FIG. 7C is a simplified schematic diagram illustrating an engineered substrate structure according to another embodiment of the present invention.

FIG. 7D is a simplified schematic diagram illustrating an engineered substrate structure according to another embodiment of the present invention.

FIG. 8A is a simplified schematic diagram illustrating an engineered substrate structure according to an embodiment of the present invention.

FIG. 8B is a simplified schematic diagram illustrating an engineered substrate structure according to another embodiment of the present invention.

FIG. 8C is a simplified schematic diagram illustrating an engineered substrate structure according to another embodiment of the present invention.

FIG. 8D is a simplified schematic diagram illustrating an engineered substrate structure according to another embodiment of the present invention.

FIG. 9 is a diagram illustrating a simplified flowchart illustrating a method of fabricating an engineered substrate structure according to an embodiment of the present invention.

FIG. 10 is a simplified schematic diagram illustrating an engineered substrate structure with eutectic growth defects according to an embodiment of the present invention.

FIG. 11A is a simplified schematic diagram illustrating a semiconductor device with defects formed in the substantially single crystal layer according to an embodiment of the present invention.

FIG. 11B is a simplified schematic diagram illustrating a semiconductor device with a eutectic barrier layer according to an embodiment of the present invention.

FIG. 11C is a simplified schematic diagram illustrating a semiconductor device with a planarization layer according to an embodiment of the present invention.

FIG. 11D is a simplified schematic diagram illustrating a semiconductor device after a CMP process according to an embodiment of the present invention.

FIG. 11E is a scanning electron microscope image of the semiconductor device after the CMP process illustrated in FIG. 11D.

FIG. 11F is a simplified schematic diagram illustrating a semiconductor device with an epitaxial buffer layer according to embodiment of the present invention.

FIG. 11G is a simplified schematic diagram illustrating a semiconductor device according to embodiment of the present invention.

FIG. 12 is a simplified schematic diagram illustrating an engineered substrate structure according to an embodiment of the present invention.

FIG. 13A is a simplified schematic diagram illustrating an engineered substrate structure according to another embodiment of the present invention.

FIG. 13B is a simplified schematic diagram illustrating an engineered substrate structure according to another embodiment of the present invention.

FIG. 13C is a simplified schematic diagram illustrating an engineered substrate structure according to another embodiment of the present invention.

FIG. 13D is a simplified schematic diagram illustrating an engineered substrate structure according to another embodiment of the present invention.

FIG. 14A is a simplified schematic diagram illustrating an engineered substrate structure according to another embodiment of the present invention.

FIG. 14B is a simplified schematic diagram illustrating an engineered substrate structure according to another embodiment of the present invention.

FIG. 14C is a simplified schematic diagram illustrating an engineered substrate structure according to another embodiment of the present invention.

FIG. 14D is a simplified schematic diagram illustrating an engineered substrate structure according to another embodiment of the present invention.

FIG. 15A is a simplified schematic diagram illustrating an engineered substrate structure according to another embodiment of the present invention.

FIG. 15B is a simplified schematic diagram illustrating an engineered substrate structure according to another embodiment of the present invention.

FIG. 15C is a simplified schematic diagram illustrating an engineered substrate structure according to another embodiment of the present invention.

FIG. 15D is a simplified schematic diagram illustrating an engineered substrate structure according to another embodiment of the present invention.

FIG. 16A is a simplified schematic diagram illustrating an engineered substrate structure according to another embodiment of the present invention.

FIG. 16B is a simplified schematic diagram illustrating an engineered substrate structure according to another embodiment of the present invention.

FIG. 16C is a simplified schematic diagram illustrating an engineered substrate structure according to another embodiment of the present invention.

FIG. 16D is a simplified schematic diagram illustrating an engineered substrate structure according to another embodiment of the present invention.

FIG. 17A is a simplified schematic diagram illustrating an engineered substrate structure according to another embodiment of the present invention.

FIG. 17B is a simplified schematic diagram illustrating an engineered substrate structure according to another embodiment of the present invention.

FIG. 17C is a simplified schematic diagram illustrating an engineered substrate structure according to another embodiment of the present invention.

FIG. 17D is a simplified schematic diagram illustrating an engineered substrate structure according to another embodiment of the present invention.

FIG. 18 is a diagram illustrating a simplified flowchart illustrating a method of fabricating an engineered substrate structure according to an embodiment of the present invention.

### DETAILED DESCRIPTION OF THE INVENTION

The growth of gallium nitride based optoelectronic and electronic structures on a sapphire substrate is a heteroepitaxial growth process since the substrate and the epitaxial layers are composed of different materials. Due to the heteroepitaxial growth process, the epitaxially grown material can exhibit a variety of adverse effects, including reduced uniformity and reductions in metrics associated with the electronic/optical properties of the epitaxial layers. As a result, engineered substrates have been developed in the past few years, and numerous benefits have been achieved over conventional techniques, as described in U.S. Pat. No. 10,297,445, which is hereby incorporated by reference in its entirety for all purposes.

For instance, engineered substrates can be coefficient of thermal expansion (CTE) matched to gallium nitride-based epitaxial layers suitable for use in optical, electronic, and optoelectronic applications. In addition, encapsulating layers utilized as components of the engineered substrate can block diffusion of impurities present in central portions of the substrate from reaching the semiconductor processing environment in which the engineered substrate is utilized. Thus, the polycrystalline ceramic core can be substantially CTE matched to a polycrystalline layer/polycrystalline shell, the epitaxial film(s) grown on the engineered substrate, or the like. The key properties associated with the substrate material, including the CTE, lattice mismatch, thermal stability, and shape control can be engineered independently for an improved (e.g., an optimized) match with gallium nitride-based epitaxial and device layers, as well as with different device architectures and performance targets. Moreover, since substrate material layers are compatible with and integrated into the conventional semiconductor fabrication processes, process integration is simplified.

However, the inventors have appreciated a number of challenges associated with the engineered substrates in relation to yttria (i.e., yttrium oxide) migration through silicon-containing layers at elevated temperatures.

During fabrication processes for semiconductor structures formed, for example, in device layers, on the engineered substrate, the engineered substrate may experience elevated temperatures (e.g., 1300° C.) in processes such as annealing, ion implantation, and the like. At these elevated temperatures, yttria that is utilized as a binding material, for example, in the polycrystalline ceramic core of the engineered substrate, can consume materials in the engineered substrate and, thereby damage the engineered substrate. This phenomenon can be referred to as yttria migration.

As an example, for an engineered substrate including a single crystal layer used as a substrate for epitaxial crystal growth, migration of yttrium and/or yttrium-based compounds from the polycrystalline ceramic core to the interface between engineered substrate and the single crystal layer can result in localized delamination of the single crystal layer and morphology defects in epitaxial layers grown on the single crystal layer.

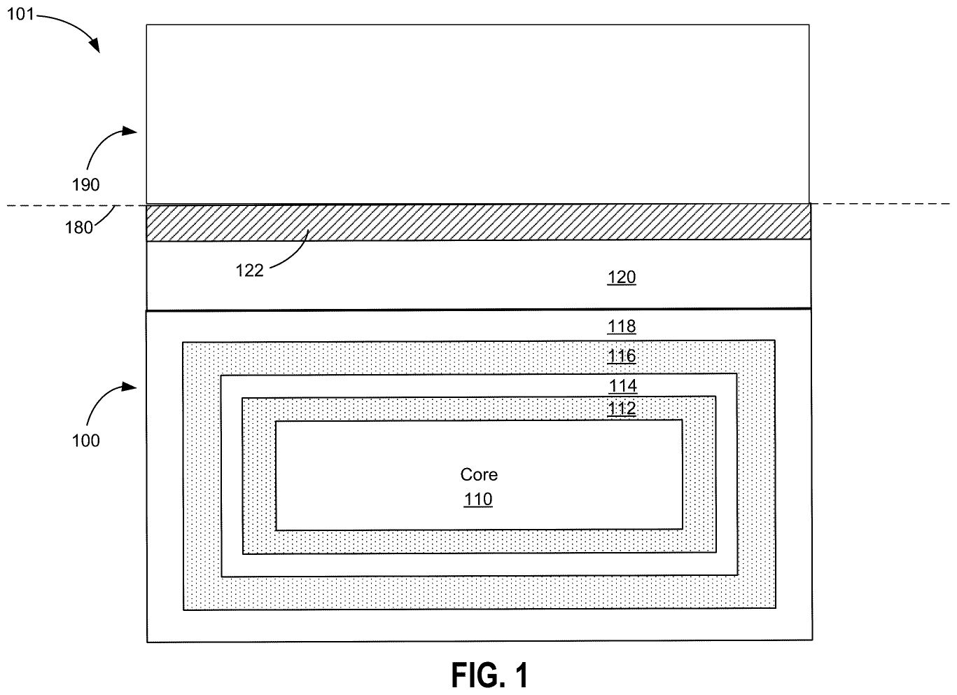

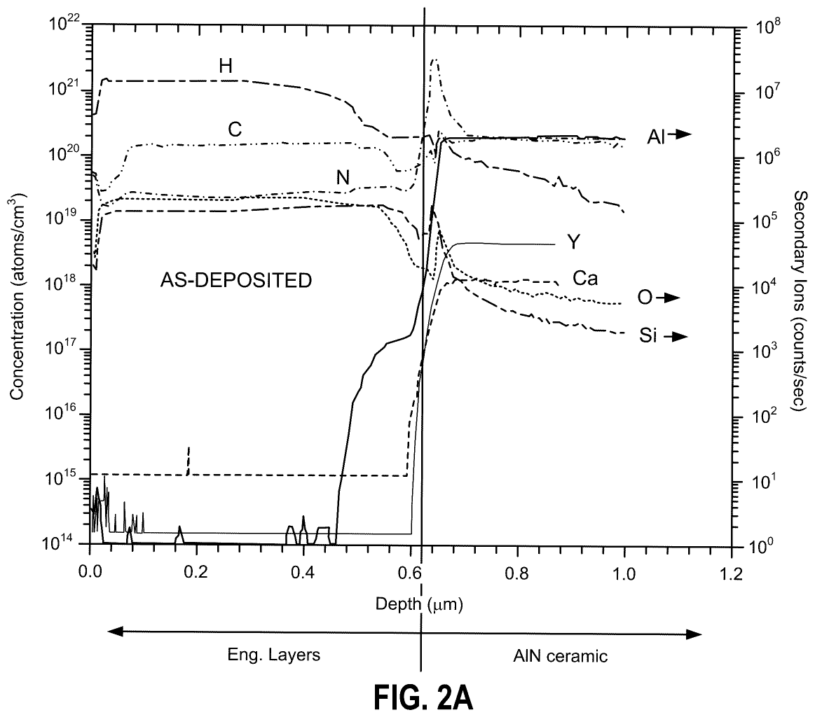

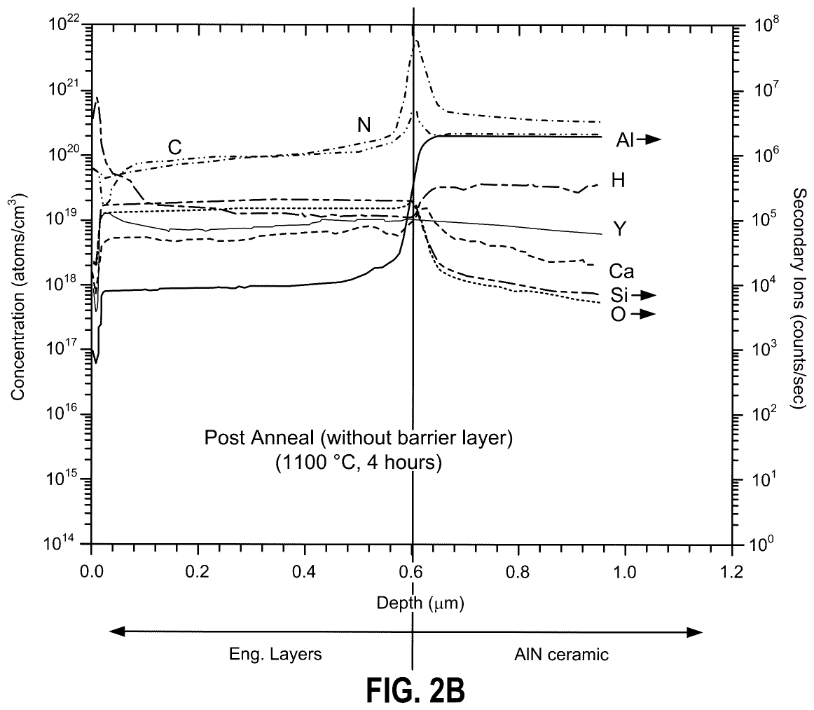

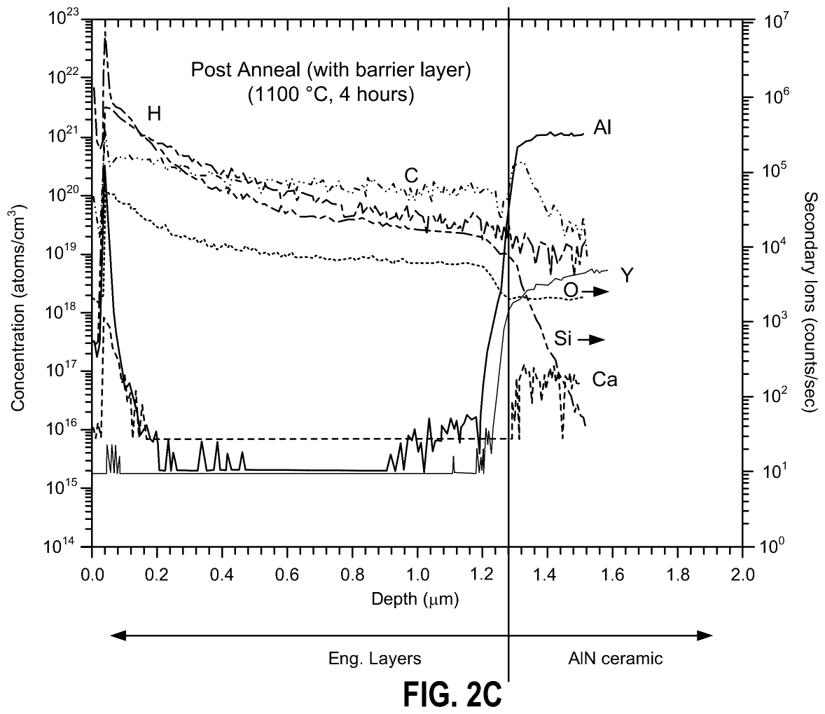

The inventors have observed that a diffusion barrier layer (e.g., a silicon nitride layer), which prevents diffusion and/or outgassing of elements present in the core of the engineered substrate, cannot prevent yttria migration at elevated temperatures, for example, temperatures greater than 1,100° C. As discussed above, yttria migration can lead to the delamination of the device layers, thereby significantly reducing the yield of semiconductor devices fabricated on the engineered substrate. Yttrium diffusion will be discussed in greater detail below with reference to FIGS. 1 and 2A-2C.

FIG. 1 is a simplified schematic diagram illustrating an engineered substrate structure. FIG. 1 is not drawn to scale. As shown in FIG. 1, a semiconductor device 101 includes an engineered substrate 100 and device layers 190 (e.g., multiple device layers) formed on the engineered substrate 100. In one example, the device layers 190 include multiple gallium nitride (GaN) epitaxial layers. Various semiconductor structures can be fabricated based on the device layers 190.

The engineered substrate 100 illustrated in FIG. 1 is suitable for a variety of electronic and optical applications. The engineered substrate includes a core 110 that can have a CTE that is substantially matched to the CTE of the epitaxial material that will be grown on the engineered substrate 100.

For applications including the growth of GaN-based materials (e.g., epitaxial layers including GaN-based layers), the core 110 can be a polycrystalline ceramic material, for example, polycrystalline aluminum nitride (AlN), which can include an yttrium-based compound (e.g., yttria) as a binding agent. Other materials can be utilized in the core 110, including polycrystalline GaN, polycrystalline aluminum gallium nitride (AlGaN), polycrystalline silicon carbide (SiC), polycrystalline zinc oxide (ZnO), polycrystalline gallium trioxide (Ga₂O₃), aluminum oxide (Al₂O₃), aluminum oxynitride (AlON), and the like.

The thickness of the core can be on the order of 100 μm to 1,500 μm, for example, 725 μm. The core 110 is encapsulated in a first adhesion layer 112 that can be referred to as a shell or an encapsulating shell. In an embodiment, the first adhesion layer 112 comprises a silicon oxide layer grown using, for example, a tetraethyl orthosilicate (TEOS) precursor. The first adhesion layer 112 can have a thickness on the order of 1,000 Å. In other embodiments, the thickness of the first adhesion layer 112 varies, for example, from 100 Å to 2,000 Å. Although a TEOS-based oxide is utilized for adhesion layers in some embodiments, other materials that provide for adhesion between later deposited layers and underlying layers or materials (e.g., ceramics, in particular, polycrystalline ceramics) can be utilized according to an embodiment of the present invention. For example, SiO₂ or other silicon oxides (SiₓO_{y}) grown using other oxide formation processes adhere well to ceramic materials and provide a suitable surface for subsequent deposition, for example, of conductive materials. In some embodiments, including the example structure shown in FIG. 1, the first adhesion layer 112 completely surrounds the core 110 to form a fully encapsulated core and can be formed using a low pressure chemical vapor deposition (LPCVD) process. The first adhesion layer 112 provides a surface on which subsequent layers adhere to form elements of the engineered substrate structure.

In addition to the use of LPCVD processes, furnace-based processes, and the like to form the encapsulating first adhesion layer, other semiconductor processes can be utilized according to embodiments of the present invention, including chemical vapor deposition (CVD) processes or similar deposition processes. As an example, a deposition process that coats a portion of the core can be utilized, the core can be flipped over, and the deposition process could be repeated to coat additional portions of the core. Thus, although LPCVD techniques are utilized in some embodiments to provide a fully encapsulated structure, other film formation techniques can be utilized depending on the particular application.

A conductive layer 114 is formed surrounding the first adhesion layer 112. In an

embodiment, the conductive layer 114 is a shell of polysilicon (i.e., polycrystalline silicon) that is formed surrounding the first adhesion layer 112. In the illustrated embodiment, first adhesion layer 112 is utilized since polysilicon can exhibit poor adhesion to ceramic materials. In embodiments in which the conductive layer is polysilicon, the thickness of the polysilicon layer can be on the order of 500-5,000 Å, for example, 2,500 Å. In some embodiments, the polysilicon layer can be formed as a shell to completely surround the first adhesion layer 112 (e.g., a TEOS-based oxide layer), thereby forming a fully encapsulated first adhesion layer, and can be formed using an LPCVD process. In other embodiments, the conductive material can be formed on a portion of the adhesion layer, for example, a lower half of the substrate structure. In some embodiments, conductive material can be formed as a fully encapsulating layer and subsequently removed on one side of the substrate structure.

In an embodiment, the conductive layer 114 can be a polysilicon layer doped to provide a highly conductive material, for example, doped with boron to provide a p-type polysilicon layer. In some embodiments, the doping with boron is at a level of 1×10¹⁹ cm⁻³ to 1×10²⁰ cm⁻³ to provide for high conductivity. Other dopants at different dopant concentrations (e.g., phosphorus, arsenic, bismuth, or the like at dopant concentrations ranging from 1×10¹⁶ cm⁻³ to 5×10¹⁸ cm⁻³) can be utilized to provide either n-type or p-type semiconductor materials suitable for use in the conductive layer. One of ordinary skill in the art would recognize many variations, modifications, and alternatives.

The presence of the conductive layer 114 is useful during electrostatic chucking of the engineered substrate to semiconductor processing tools, for example, tools with an electrostatic chuck (ESC). The conductive layer 114 enables rapid dechucking after processing in the semiconductor processing tools. Thus, embodiments of the present invention provide substrate structures that can be processed in manners utilized with conventional silicon wafers. One of ordinary skill in the art would recognize many variations, modifications, and alternatives.

A second adhesion layer 116 (e.g., a TEOS-based oxide layer on the order of 1,000 Å in thickness) is formed surrounding the conductive layer 114. In some embodiments, the second adhesion layer 116 completely surrounds the conductive layer 114 to form a fully encapsulated structure and can be formed using an LPCVD process, a CVD process, or any other suitable deposition process, including the deposition of a spin-on dielectric.

A diffusion barrier layer 118, for example, a silicon nitride layer, is formed surrounding the second adhesion layer 116. In an embodiment, the diffusion barrier layer 118 is a silicon nitride layer that is on the order of 2,000 Å to 5,000 Å in thickness. The diffusion barrier layer 118 completely surrounds the second adhesion layer 116 in some embodiments to form a fully encapsulated structure and can be formed using an LPCVD process. In addition to silicon nitride layers, amorphous materials including SiCN, SiON, AlN, SiC, and the like can be utilized as diffusion barrier layers. In some implementations, the diffusion barrier layer 118 comprises a number of sub-layers that are built up to form the diffusion barrier layer. Thus, the term diffusion barrier layer is not intended to denote a single layer or a single material, but to encompass one or more materials layered in a composite manner. One of ordinary skill in the art would recognize many variations, modifications, and alternatives.

In some embodiments, the diffusion barrier layer 118, e.g., a silicon nitride layer, prevents diffusion and/or outgassing of elements present in the core 110, for example, yttrium, yttria, oxygen, metallic impurities, other trace elements, and the like into the environment of the semiconductor processing chambers in which the engineered substrate could be present, for example, during a high temperature (e.g., 1,000° C.) epitaxial growth process. Importantly, utilizing the encapsulating layers described herein, ceramic materials, including polycrystalline AlN that are designed for non-clean room environments, can be utilized in semiconductor process flows and clean room environments. The expensive clean room environments are therefore protected.

In the example shown in FIG. 1, a bonding layer 120 (e.g., a silicon oxide layer) is deposited on a portion of the diffusion barrier layer 118, for example, the top surface of the diffusion barrier layer, and subsequently used during the bonding of a substantially single crystalline layer 122, e.g., a single crystalline silicon layer. The bonding layer 120 can be approximately 1.5 um in thickness in some embodiments.

The substantially single crystalline layer 122 is suitable for use as a growth layer during an epitaxial growth process for the formation of the device layers 190. In some embodiments, the device layers 190 include an epitaxial material layer. In one example, the epitaxial material layer includes a GaN layer 2 μm to 10 μm in thickness, which can be utilized as one of a plurality of layers utilized in optoelectronic devices, RF devices, power devices, and the like. In an embodiment, the substantially single crystalline layer 122 includes a substantially single crystalline silicon layer that is attached to the silicon oxide layer using a layer transfer process. In other embodiments, the substantially single crystalline layer 122 can include, for example, SiC, sapphire, GaN, AlN, SiGe, Ge, diamond, Ga₂O₃, AlGaN, InGaN, InN, and/or ZnO. In some embodiments, the substantially single crystalline layer 122 can have a thickness from 0 to 0.5 μm. The crystalline layers of the epitaxial material are an extension of the underlying semiconductor lattice associated with the substantially single crystalline layer 122. The unique CTE matching properties of the engineered substrate enable growth of thicker epitaxial material than existing technologies.

As briefly discussed above, at an elevated temperature, binding agents such as yttrium-based compounds or other elements/compounds can migrate and consume layers of the engineered substrate. Although, as discussed in relation to FIGS. 2A-2C, diffusion of yttrium does not occur at substantial levels at temperatures up to 1,100° C., the inventors have determined that yttrium and/or yttria migration occurs at higher temperatures and can result in degradation of the quality of engineered layers present in the engineered substrate, including delamination of layers in some cases.

FIG. 2A is a secondary ion mass spectroscopy (SIMS) profile illustrating species concentration (as-deposited) as a function of depth for an engineered structure according to an embodiment of the present invention. The engineered structure did not include the diffusion barrier layer 118 shown in FIG. 1. Referring to FIG. 2A, several species present in the ceramic core (e.g., yttrium, calcium, and aluminum) drop to negligible concentrations in the bonding layer 120 and the substantially single crystalline layer 122 (collectively, the engineered layers 120/122). The concentrations of calcium, yttrium, and aluminum drop by three, four, and six orders of magnitude, respectively.

FIG. 2B is a SIMS profile illustrating species concentration (after anneal) as a function of depth for an engineered structure without a diffusion barrier layer according to an embodiment of the present invention. As discussed above, during semiconductor processing operations, the engineered substrate structures provided by embodiments of the present invention can be exposed to high temperatures (˜1,100° C.) for several hours, for example, during epitaxial growth of GaN-based layers.

For the profile illustrated in FIG. 2B, the engineered substrate structure was annealed at 1,100° C. for a period of four hours. As shown by FIG. 2B, calcium, yttrium, and aluminum, originally present in low concentrations in the as deposited sample, have diffused into the engineered layers, reaching concentrations similar to other elements.

FIG. 2C is a SIMS profile illustrating species concentration (after anneal) as a function of depth for an engineered structure with a diffusion barrier layer according to an embodiment of the present invention. The integration of the diffusion barrier layer 118 (e.g., a silicon nitride layer) into the engineered substrate structure prevents the diffusion of calcium, yttrium, and aluminum into the engineered layers during the annealing process that occurred when the diffusion barrier layer was not present. As illustrated in FIG. 2C, calcium, yttrium, and aluminum present in the ceramic core remain at low concentrations in the engineered layers post-anneal. Thus, the use of the diffusion barrier layer 118 (e.g., a silicon nitride layer) prevents these elements from diffusing through the diffusion barrier layer and thereby prevents their release into the environment surrounding the engineered substrate. Similarly, any other impurities contained within the bulk ceramic material would be contained by the diffusion barrier layer.

Typically, ceramic materials utilized to form the core 110 are fired at temperatures in the range of 1,800° C. It would be expected that this process would drive out a significant amount of impurities present in the ceramic materials. These impurities can include yttrium, which results from the use of yttria as sintering agent, calcium, and other elements and compounds. Subsequently, during epitaxial growth processes, which are conducted at much lower temperatures in the range of 800° C. to 1,100° C., it would be expected that the subsequent diffusion of these impurities would be insignificant. However, contrary to conventional expectations, the inventors have determined that even during epitaxial growth processes at temperatures much less than the firing temperature of the ceramic materials, significant diffusion of elements through the layers of the engineered substrate can occur. Thus, as shown in FIG. 2C in contrast to FIG. 2B, the diffusion barrier layer 118 (e.g., a silicon nitride layer) can prevent out-diffusion of the background elements from the polycrystalline ceramic material (e.g., AlN) into the engineered layers 120/122 and the device layers 190. The diffusion barrier layer 118 encapsulating the underlying layers and material provides the desired diffusion barrier layer functionality.

As illustrated in FIG. 2B, elements originally present in the core 110, including yttrium, diffuse into and through the first adhesion layer 112, the conductive layer 114, and the second adhesion layer 116. However, the presence of the diffusion barrier layer 118 prevents these elements from diffusing through the diffusion barrier layer 118 and thereby prevents their release into the environment surrounding the engineered substrate at annealing temperatures up to 1,100° C., as illustrated in FIG. 2C.

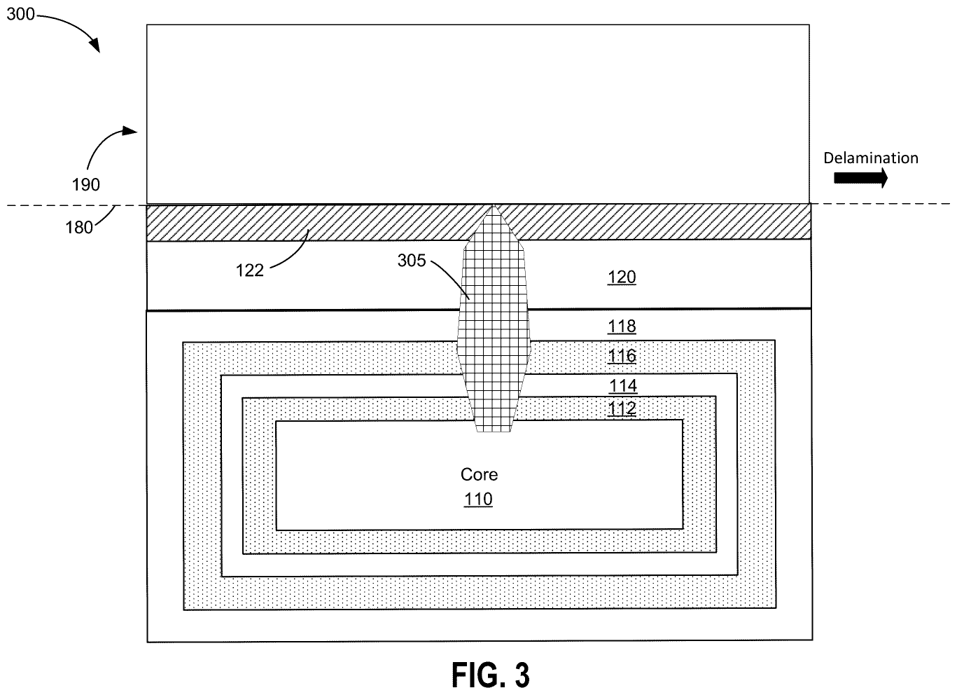

However, as mentioned above, the inventors have observed that the diffusion barrier layer 118 illustrated in FIGS. 1 and 3, for example, a silicon nitride layer, which prevents diffusion and/or outgassing of elements present in the core 110 of the engineered substrate at epitaxial growth temperatures on the order of 1,100° C., does not prevent the migration of yttrium-based compounds, including yttria, at elevated temperatures greater than 1,100° C.

FIG. 3 is a simplified schematic diagram illustrating a semiconductor device with yttrium-based compound migration according to an embodiment of the present invention. As illustrated in FIG. 3, an engineered substrate 300 in which an yttrium-based compound structure 305 is formed as the yttrium-based compounds (e.g., yttria) in the core 110 consume a portion of one or more of the core 110, the first adhesion layer 112, the conductive layer 114, the second adhesion layer 116, the diffusion barrier layer 118, the bonding layer 120, and/or the substantially single crystalline layer 122. The yttria percent composition (by weight) in the core 110 is typically between 1% and 5%, for example, in some cases, between 3% and 5%. At these concentrations, binding agent grains will be exposed at the surface of the polycrystalline ceramic core (rather than being covered by the material of the polycrystalline ceramic core) and, therefore, in physical contact with adjacent layers, including layers containing silicon and/or oxygen. Thus, as discussed above, the binding agent can react with and consume one or more films/layers in the engineered substrate 300, which may cause localized delamination where the yttrium-based compound structure 305 deforms the interface 180 between the engineered substrate 300 and the device layers 190.

As discussed above, the polycrystalline ceramic core can include not only polycrystalline AlN or other suitable materials, but also yttrium-based materials, including yttria, as a binding agent. For many GaN-based semiconductor process steps, including epitaxial growth, the processing temperatures are under 1100° C. and the diffusion barrier layer 118 illustrated in FIG. 1 is sufficient to prevent diffusion of yttrium-based compounds, including yttria, through the diffusion barrier layer as shown in FIG. 2C.

However, the inventors have determined that at high temperatures associated with some semiconductor processes, for instance, implant activation, (e.g., temperatures greater than 1100° C., for example, on the order of 1200° C. or 1300°° C.), the yttrium-based compounds present in the polycrystalline ceramic core can migrate and subsequently react, for example, with silicon-containing materials, including silicon oxide, silicon nitride, and polycrystalline silicon and/or oxygen-containing materials. Without limiting embodiments of the present invention, the inventors believe that yttrium and silicon, either as single crystal silicon or polycrystalline silicon, form a eutectic mixture that melts at a temperature lower than the melting points of either yttrium or silicon. As a result, at elevated temperatures, the yttrium and/or yttria migrates through silicon-containing layers as illustrated in FIG. 3. At these elevated temperatures greater than 1100° C., for example, on the order of 1200° C. or 1300° C., the diffusion barrier layer 118 is not effective in preventing the migration of the eutectic mixture, although it can be sufficient to prevent the atomic or molecular diffusion of elements such as yttrium, as shown in FIG. 2C.

Referring to FIG. 3, the yttrium-based compound structure 305 may migrate or penetrate through a portion of one or more of the core 110, the first adhesion layer 112, the conductive layer 114, the second adhesion layer 116, the diffusion barrier layer 118, the bonding layer 120, and/or the substantially single crystalline layer 122. In some examples, the yttrium-based compound structure 305 may even reach the interface 180 between the engineered substrate 300 and the device layers 190. As a result, the mechanical bonding strength between the engineered substrate 100 and the device layers 190 is weakened. Therefore, delamination of the device layers 190 may occur, as illustrated by the arrow shown in FIG. 3.

In order to address problems resulting from the migration of yttrium-based compounds from the polycrystalline ceramic core and consumption of engineered films coupled to the polycrystalline ceramic core as illustrated in FIG. 3, embodiments of the present invention provide an engineered substrate that includes a eutectic barrier layer. The inventors have determined that the eutectic barrier layer can prevent the migration of yttrium-based compounds caused by the eutectic mixture. As described more fully herein, the eutectic barrier layer can serve to prevent yttrium-based compounds present in the polycrystalline ceramic core from migrating from the polycrystalline ceramic core to outer portions of the engineered substrate, particularly, layers of the engineered substrate adjacent the diffusion barrier layer 118, the bonding layer 120, and the substantially single crystalline layer 122.

Importantly, adding the eutectic barrier layer is not a mere rearrangement of layers or duplication of a barrier layer. As will be fully discussed below, although the eutectic barrier layer functions as a barrier to migration of compounds, the presence of the eutectic barrier layer in the engineered substrate is not merely the diffusion barrier layer 118 being shifted to a different position in the engineered substrate. In fact, the eutectic barrier layer and the diffusion barrier layer have different principles of operation and function as barriers at different temperature ranges. Moreover, the eutectic barrier layer modifies the physical structure of the engineered substrate. The inventors have determined that the introduction of the eutectic barrier layer produces the unexpected result that the migration of compounds is prevented even though this migration was not prevented by the existing diffusion barrier. Therefore, the functionality of the eutectic barrier layer included in the engineered substrate was not expected until discovered by the inventors.

Moreover, the eutectic barrier layer is positioned at a location that is closer to the polycrystalline ceramic core than the bonding layer 120. This position of the eutectic barrier layer is utilized because the interface between the bonding layer 120 and the substantially single crystalline layer 122 is susceptible to delamination. Since the eutectic barrier layer is closer to the polycrystalline ceramic core than the bonding layer 120, it can prevent the migration of yttrium-based compounds caused by the eutectic mixture from reaching the bonding layer 120. Thus, embodiments, of the present invention include the use of a eutectic barrier layer positioned between the polycrystalline ceramic core 110 and the bonding layer 120 in order to contain the migration of yttrium-based compounds.

In one embodiment, the eutectic barrier layer comprises an AlN layer. In other embodiments, the eutectic barrier layer comprises an AlON layer, an Al₂O₃ layer, a TaN layer, a TiN layer, or combinations thereof. In other embodiments, the eutectic barrier layer may comprise suitable elements or compounds. In some implementations, a eutectic adhesion layer is utilized to couple the eutectic barrier layer to other layer(s) included in the engineered substrate. The eutectic adhesion layer may comprise silicon oxide, TEOS-based oxides, silicon oxynitride, or combinations thereof. In other implementations, the interface between the eutectic barrier layer and other layer(s) included in the engineered substrate may be preprepared using a suitable surface preparation technique. In some embodiments, the eutectic barrier layer is formed on one side (e.g., the front side facing the device layers to be formed on the engineered substrate) of the polycrystalline ceramic core. In other embodiments, the eutectic barrier layer is formed on both sides (e.g., the front side and the back side opposite to the front side) of the polycrystalline ceramic core. In one example, the eutectic barrier layer encapsulates the polycrystalline ceramic core and other intervening layer(s) included in the engineered substrate. The eutectic barrier layer can be formed using atomic layer deposition (ALD), physical vapor deposition (PVD), chemical vapor deposition (CVD), metal organic chemical vapor deposition (MOCVD), electro or electroless plating, or other suitable techniques.

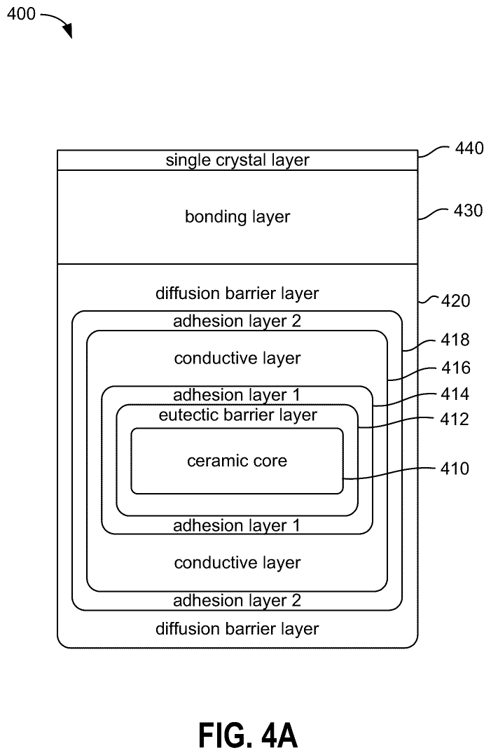

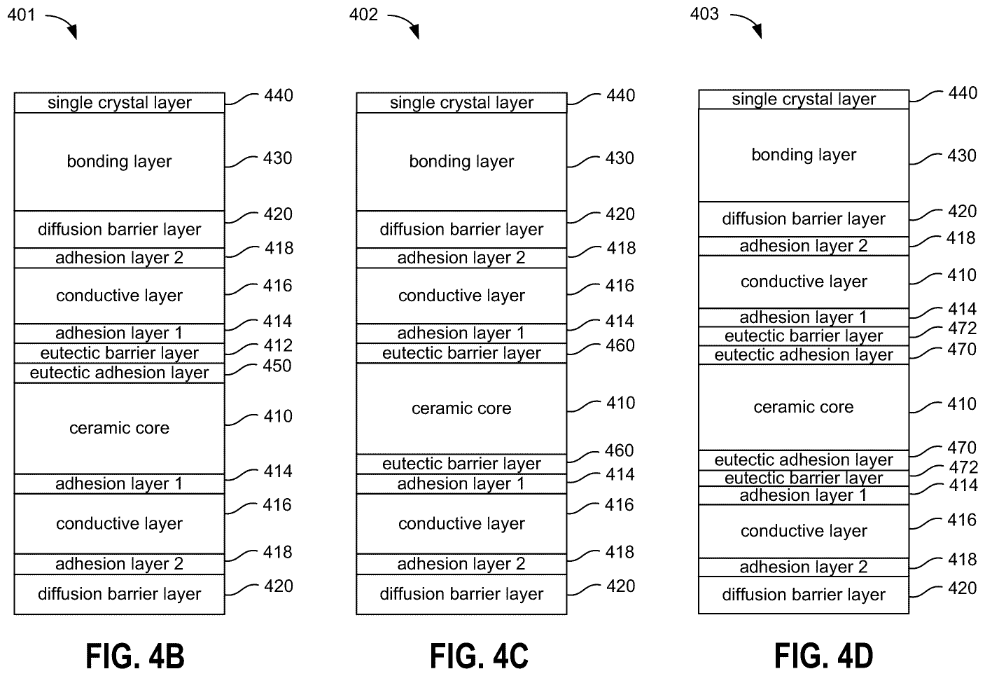

FIG. 4A is a simplified schematic diagram illustrating an engineered substrate structure according to an embodiment of the present invention. FIG. 4B is a simplified schematic diagram illustrating an engineered substrate structure according to another embodiment of the present invention. FIG. 4C is a simplified schematic diagram illustrating an engineered substrate structure according to another embodiment of the present invention. FIG. 4D is a simplified schematic diagram illustrating an engineered substrate structure according to another embodiment of the present invention. The engineered substrate illustrated in FIGS. 4A-4D share common elements with the engineered substrate illustrated in FIG. 1 and the discussion provided in relation to the engineered substrate illustrated in FIG. 1 is applicable to the engineered substrate illustrated in FIGS. 4A-4D as appropriate.

As shown in FIG. 4A, the engineered substrate 400 includes a polycrystalline ceramic core 410 and a eutectic barrier layer 412 coupled to the polycrystalline ceramic core. The engineered substrate 40A also includes a first adhesion layer 414 coupled to the eutectic barrier layer 412 and a conductive layer 416 coupled to the first adhesion layer 414. The engineered substrate 400 also includes a second adhesion layer 418 coupled to the conductive layer 416 and a diffusion barrier layer 420 coupled to the second adhesion layer 418. As illustrated in FIG. 4A, in this embodiment, the first adhesion layer 414 encapsulates the polycrystalline ceramic core 410 and the eutectic barrier layer 414, the conductive layer 416 encapsulates the first adhesion layer 414, the second adhesion layer 418 encapsulates the conductive layer 416, and the diffusion barrier layer 420 encapsulates the second adhesion layer 418. Although this cross-sectional view only illustrates encapsulation in the plane of the figure, it will be appreciated that the peripheral surfaces of the various layers will also be encapsulated in the planes behind and in front of the plane of the figure. One of ordinary skill in the art would recognize many variations, modifications, and alternatives.

The engineered substrate 400 also includes a bonding layer 430 coupled to the diffusion barrier layer 420 and a substantially single crystal layer 440 coupled to the bonding layer 430. Although the layers shown in FIG. 4A stop at the substantially single crystal layer 440, the engineered substrate 400 may also include an epitaxial III-V layer coupled to the substantially single crystal layer 440. In some embodiments, the epitaxial III-V layer is an epitaxial GaN layer or GaN-based layer, and the substantially single crystal layer 440 comprises a silicon (111) layer. In other embodiments, the substantially single crystal layer 440 can include, for example, SiC, sapphire, GaN, AlN, SiGe, Ge, diamond, Ga₂O₃, AlGaN, InGaN, InN, and/or ZnO. In some embodiments, the substantially single crystal layer 440 can have a thickness from 0 to 0.5 μm. The substantially single crystal layer 440 is suitable for use as a growth layer during an epitaxial growth process for the formation of epitaxial material thereon. The crystalline layers of the epitaxial material are an extension of the underlying semiconductor lattice associated with the substantially single crystal layer 440. The unique CTE matching properties of the engineered substrate 400 enable growth of thicker epitaxial material than existing technologies.

Moreover, as discussed above, the eutectic barrier layer 412 can prevent the migration of yttrium-based compounds caused by the eutectic mixture from reaching the bonding layer 430. The eutectic barrier layer 412 may also serve to prevent the atomic or molecular diffusion of elements such as yttrium like the diffusion barrier layer 420, as shown in FIG. 2C. To some extent, the eutectic barrier layer 412 may serve as a dual-function barrier layer, constraining both atomic or molecular diffusion and eutectic consumption. In such a case, a diffusion barrier layer positioned farther from the polycrystalline ceramic core than the eutectic barrier layer may become optional or redundant.

In addition, although the embodiment shown in FIG. 4A has been illustrated with various layers, a person of ordinary skill in the art would appreciate that one or more of these layers may be optional, depending on the particular structure and/or fabrication process. By way of example, in some cases, if the diffusion barrier layer (which typically includes silicon nitride) is suitable for being deposited directly on the conductive layer (which typically includes polysilicon), the second adhesion layer can be omitted. Therefore, one or more of these layers may be optional, depending on the particular structure and/or fabrication process.

As shown in FIG. 4B, this embodiment of the engineered substrate 401 includes a eutectic adhesion layer 450 that is coupled between the polycrystalline ceramic core 410 and the eutectic barrier layer 412. The eutectic adhesion layer 450 can facilitate the coupling between the polycrystalline ceramic core 410 and the eutectic barrier layer 412. Typically, a good candidate material for a barrier layer is not a good candidate material for an adhesion layer, because a good candidate material for a barrier layer is typically stiff and dense and does not adhere well to a surface. The eutectic barrier layer 412 may be subject to these material properties. Therefore, a thin eutectic adhesion layer formed at the interface between the eutectic barrier layer 412 and another layer increases the adhesion strength. In some embodiments, a thin eutectic adhesion layer surrounds the surface of the eutectic barrier layer. In addition, surface preparation techniques such as cleaning of the surface or plasma activation can improve the adhesion between the eutectic barrier layer 412 and another layer. Although encapsulation by the first adhesion layer 414, the conductive layer 416, the second adhesion layer 418, and the diffusion barrier layer 420 is not illustrated in FIG. 4B for purposes of clarity, as well as FIGS. 4C and 4D below, it will be appreciated that encapsulation by these layers is included within the scope of the present invention. One of ordinary skill in the art would recognize many variations, modifications, and alternatives.

As shown in FIG. 4C, the eutectic barrier layer 460 can be formed on both sides (i.e., the front side and the back side) as well as the peripheral surfaces extending between the front side and the back side of the polycrystalline ceramic core 410 in this embodiment of engineered substrate 402. Thus, although the eutectic barrier layer 460 is only illustrated as being formed on both sides (i.e., the front side and the back side) of the polycrystalline ceramic core 410, it should be understood that in a manner similar to first adhesion layer 412 encapsulating polycrystalline ceramic core 410 and eutectic barrier layer 412 as illustrated in FIG. 4A, eutectic barrier layer 460 can be formed on the peripheral surfaces and encapsulate polycrystalline ceramic core 410.

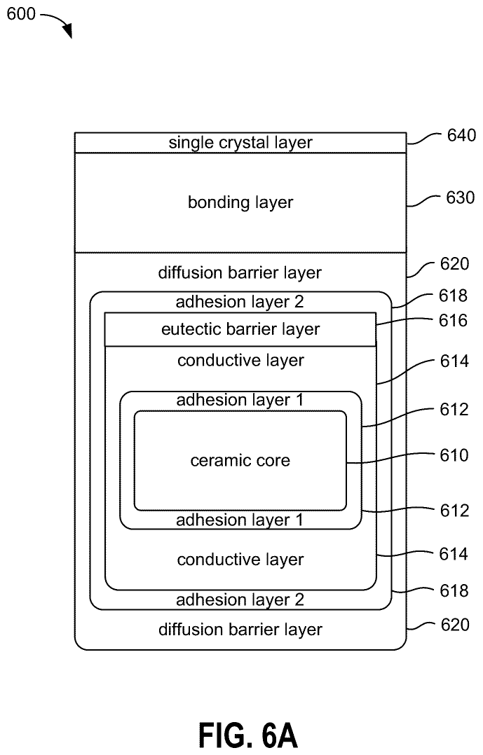

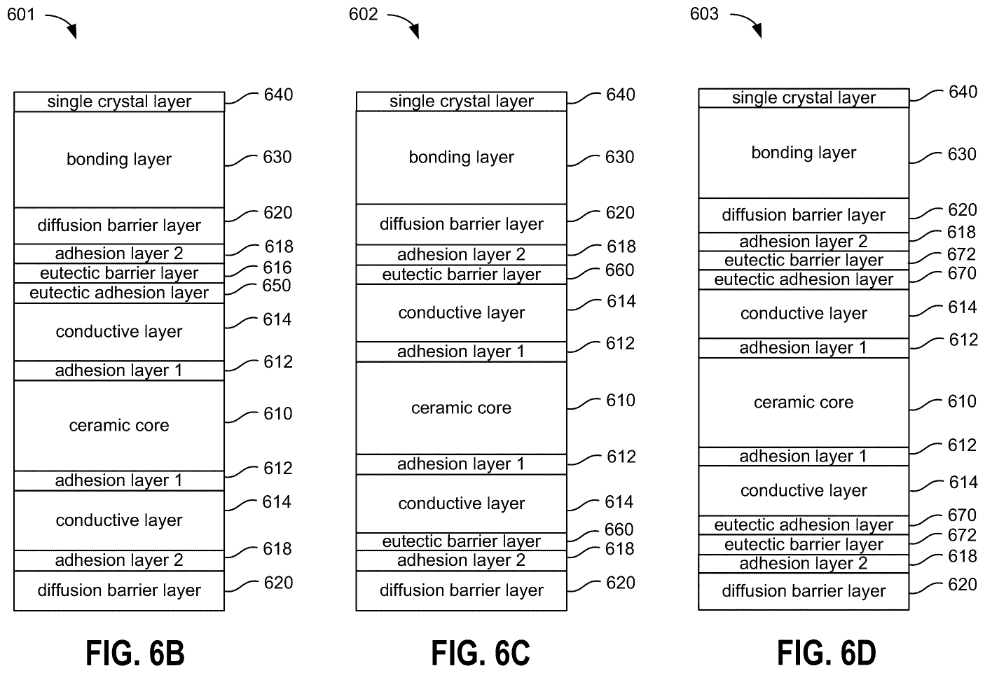

Thus, in some embodiments, not only is the eutectic barrier layer coupled to the front surface (the surface facing the device layers 190 shown in FIG. 1) of the polycrystalline ceramic core, but also to the back surface (the surface opposite to the front surface) of the polycrystalline ceramic core, as well as the side (i.e., peripheral) surface(s) of the polycrystalline ceramic core. Some deposition techniques (e.g., PVD) are particularly well suited for use for single-sided deposition, whereas some deposition techniques (e.g., ALD) are particularly well suited for an encapsulating deposition in which both surfaces of the substrate, as well as the sides of the substrate, can be coated. In some implementations, deposition on both surfaces of the substrate and/or an encapsulating deposition can be performed via a single-side deposition followed by flipping the substrate and repeating the single-side deposition process. Moreover, there are other considerations that can be utilized in determining the suitable deposition technique(s) that are used. For example, if ALD is used to deposit the eutectic barrier layer, this is generally performed after deposition of the conductive layer, e.g., a polysilicon layer. As will be discussed below, this process flow is used in the embodiments shown in FIGS. 6A-6D, 7A-7D, and 8A-8D. One of ordinary skill in the art would recognize many variations, modifications, and alternatives.

Likewise, in some embodiments, the first adhesion layer 414 encapsulates the eutectic barrier layer 460, the conductive layer 416 encapsulates the first adhesion layer 414, the second adhesion layer 418 encapsulates the conductive layer 416, and the diffusion barrier layer 420 encapsulates the second adhesion layer 418.

As shown in FIG. 4D, for engineered substrate 403, the eutectic barrier layer 472 can be formed on both sides (i.e., the front side and the back side) of the polycrystalline ceramic core 410, and the eutectic adhesion layer is coupled between the polycrystalline ceramic core 410 and the eutectic barrier layer 472 on both sides (i.e., the front side and the back side). In other words, the embodiment shown in FIG. 4D is a combination of those shown in FIGS. 4B and 4C. As discussed above, although encapsulation is accomplished by forming a particular layer on both sides of the underlying layer, it is not illustrated in some figures herein for purposes of clarity. One of ordinary skill in the art would recognize many variations, modifications, and alternatives.

In some embodiments, the polycrystalline ceramic core comprises AlN, the first adhesion layer comprises a first TEOS-based oxide layer, the conductive layer comprises a polysilicon layer, the second adhesion layer comprises a second TEOS-based oxide layer, the diffusion barrier layer comprises a silicon nitride layer. In some embodiments, the bonding layer comprises an oxide layer formed by PECVD. In some embodiments, the substantially single crystalline layer comprises a silicon (111) layer.

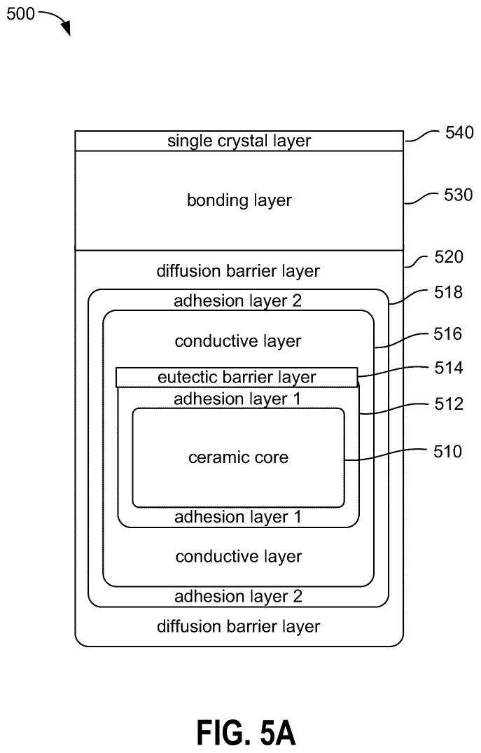

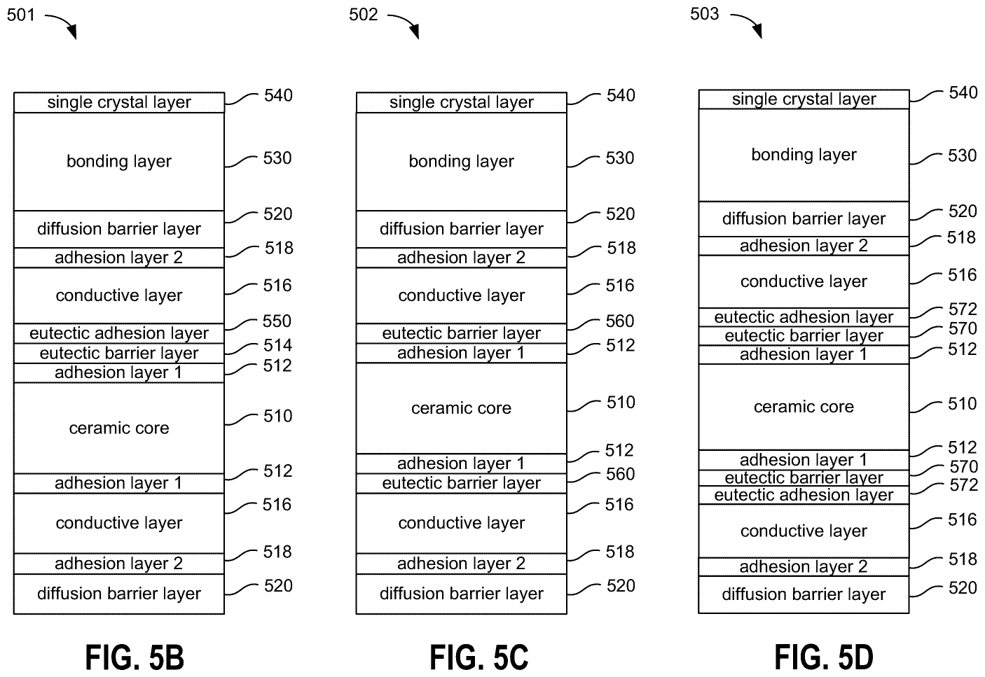

FIG. 5A is a simplified schematic diagram illustrating an engineered substrate structure according to an embodiment of the present invention. FIG. 5B is a simplified schematic diagram illustrating an engineered substrate structure according to another embodiment of the present invention. FIG. 5C is a simplified schematic diagram illustrating an engineered substrate structure according to another embodiment of the present invention. FIG. 5D is a simplified schematic diagram illustrating an engineered substrate structure according to another embodiment of the present invention. The engineered substrate illustrated in FIGS. 5A-5D share common elements with the engineered substrate illustrated in FIGS. 1 and 4A-4D and the discussion provided in relation to the engineered substrate illustrated in FIGS. 1 and 4A-4D is applicable to the engineered substrate illustrated in FIGS. 5A-5D as appropriate.

As shown in FIG. 5A, the engineered substrate 500 includes a polycrystalline ceramic core 510 and a first adhesion layer 512 coupled to the polycrystalline ceramic core 510. The engineered substrate 500 also includes a eutectic barrier layer 514 coupled to the first adhesion layer 512 and a conductive layer 516 coupled to the eutectic barrier layer 514. The engineered substrate also includes a second adhesion layer 518 coupled to the conductive layer 516 and a diffusion barrier layer 520 coupled to the second adhesion layer 518. As illustrated in FIG. 5A, in this embodiment, the first adhesion layer 514 encapsulates the polycrystalline ceramic core 410, the conductive layer 416 encapsulates the eutectic barrier layer 514 and the first adhesion layer 414, the second adhesion layer 418 encapsulates the conductive layer 416, and the diffusion barrier layer 420 encapsulates the second adhesion layer 418. Although this cross-sectional view only illustrates encapsulation in the plane of the figure, it will be appreciated that the peripheral surfaces of the various layers will also be encapsulated in the planes behind and in front of the plane of the figure. One of ordinary skill in the art would recognize many variations, modifications, and alternatives.

The engineered substrate 500 also includes a bonding layer 530 coupled to the diffusion barrier layer 520 and a substantially single crystal layer 540 coupled to the bonding layer 530. The engineered substrate may also include an epitaxial III-V layer coupled to the substantially single crystal layer 540.

As shown in FIG. 5B, a eutectic adhesion layer is coupled between the eutectic barrier layer and the conductive layer. The eutectic adhesion layer can facilitate the coupling between the eutectic barrier layer and the conductive layer. As shown in FIG. 5B, this embodiment of the engineered substrate 501 includes a eutectic adhesion layer 550 that is coupled between the polycrystalline ceramic core 510 and the eutectic barrier layer 514. The eutectic adhesion layer 550 can facilitate the coupling between the polycrystalline ceramic core 510 and the eutectic barrier layer 514. In some embodiments, a thin eutectic adhesion layer surrounds the surface of the eutectic barrier layer. In addition, surface preparation techniques such as cleaning of the surface or plasma activation can improve the adhesion between the eutectic barrier layer 514 and another layer. Although encapsulation by the first adhesion layer 512, the conductive layer 516, the second adhesion layer 518, and the diffusion barrier layer 520 is not illustrated in FIG. 5B for purposes of clarity, as well as FIGS. 5C and 5D below, it will be appreciated that encapsulation by these layers is included within the scope of the present invention. One of ordinary skill in the art would recognize many variations, modifications, and alternatives.

As shown in FIG. 5C, the eutectic barrier layer can be formed on both sides (i.e., the front side and the back side) of the first adhesion layer as well as the peripheral surfaces extending between the front side and the back side of the first adhesion layer in this embodiment of engineered substrate 502. Thus, although the eutectic barrier layer 560 is only illustrated as being formed on both sides (i.e., the front side and the back side) of the first adhesion layer 512, it should be understood that eutectic barrier layer 560 can be formed on the peripheral surfaces and encapsulate the first adhesion layer 512.

In one embodiment, the first adhesion layer 512 encapsulates the polycrystalline ceramic core, the eutectic barrier layer 560 encapsulates the first adhesion layer 512, the conductive layer 516 encapsulates the eutectic barrier layer 560, the second adhesion layer 518 encapsulates the conductive layer 516, and the diffusion barrier layer 520 encapsulates the second adhesion layer 518.

Referring to both FIG. 5A and FIG. 5C, in the embodiment shown in FIG. 5A, the eutectic barrier layer 514 is positioned on one side of the polycrystalline ceramic core 510 and the diffusion barrier layer 520 encapsulates the polycrystalline ceramic core 510. In the embodiment shown in FIG. 5C, the eutectic barrier layer 560 encapsulates the polycrystalline ceramic core 510 and the diffusion barrier layer 520 encapsulates the polycrystalline ceramic core 510 as well.

As shown in FIG. 5D, for engineered substrate 503, the eutectic barrier layer 570 can be formed on both sides (i.e., the front side and the back side) of the first adhesion layer 512, and the eutectic adhesion layer 572 is coupled between the eutectic barrier layer 570 and the conductive layer 516 on both sides (i.e., the front side and the back side) as well as the peripheral sides. In other words, the embodiment shown in FIG. 5D is a combination of those shown in FIGS. 5B and 5C. As discussed above, although encapsulation is accomplished by forming a particular layer on both sides of the underlying layer, it is not illustrated in some figures herein for purposes of clarity. One of ordinary skill in the art would recognize many variations, modifications, and alternatives.

In some embodiments, the polycrystalline ceramic core comprises AlN, the first adhesion layer comprises a first TEOS-based oxide layer, the conductive layer comprises a polysilicon layer, the second adhesion layer comprises a second TEOS-based oxide layer, the diffusion barrier layer comprises a silicon nitride layer. In some embodiments, the bonding layer comprises an oxide layer formed by PECVD. In some embodiments, the substantially single crystalline layer comprises a silicon (111) layer.

FIG. 6A is a simplified schematic diagram illustrating an engineered substrate structure according to an embodiment of the present invention. FIG. 6B is a simplified schematic diagram illustrating an engineered substrate structure according to another embodiment of the present invention. FIG. 6C is a simplified schematic diagram illustrating an engineered substrate structure according to another embodiment of the present invention. FIG. 6D is a simplified schematic diagram illustrating an engineered substrate structure according to another embodiment of the present invention. The engineered substrate illustrated in FIGS. 6A-6D share common elements with the engineered substrate illustrated in FIGS. 1 and 4A-4D and the discussion provided in relation to the engineered substrate illustrated in FIGS. 1 and 4A-4D is applicable to the engineered substrate illustrated in FIGS. 6A-6D as appropriate.

As shown in FIG. 6A, the engineered substrate 600 includes a polycrystalline ceramic core 610 and a first adhesion layer 612 coupled to the polycrystalline ceramic core 610. The engineered substrate also includes a conductive layer 614 coupled to the first adhesion layer 612 and a eutectic barrier layer 616 coupled to the conductive layer 614. The engineered substrate 600 also includes a second adhesion layer 618 coupled to the eutectic barrier layer 616 and a diffusion barrier layer 620 coupled to the second adhesion layer 618. The engineered substrate 600 also includes a bonding layer 630 coupled to the diffusion barrier layer 620 and a substantially single crystal layer 640 coupled to the bonding layer 630. The engineered substrate may also include an epitaxial III-V layer coupled to the substantially single crystal layer.

Although the second adhesion layer 616 is positioned between the eutectic barrier layer 614 and the diffusion barrier layer 620 in the embodiment shown in FIG. 6A, it is possible in another embodiment that the eutectic barrier layer 616 is coupled to the diffusion barrier layer 620 without the second adhesion layer 618 therebetween. Thus, the eutectic barrier layer 616 and the diffusion barrier layer 620 can form a double barrier layer structure, which collectively constrains or prevents both atomic or molecular diffusion and eutectic consumption/migration.

Because the eutectic barrier layer 616 is positioned between the polycrystalline ceramic core 610 and the bonding layer 630, even if the yttrium-based compound structure consumes a portion of the polycrystalline ceramic core 410, the first adhesion layer 412, and the conductive layer 614, the resulting migration will not reach the bonding layer 630. As a result, the bonding strength at the interface between the bonding layer 630 and the substantially single crystalline layer 640 is maintained.

As shown in the illustration of engineered substrate 601 in FIG. 6B, a eutectic adhesion layer 650 is coupled between the eutectic barrier layer 616 and the conductive layer 614. The eutectic adhesion layer 650 can facilitate the coupling between the eutectic barrier layer 616 and the conductive layer 614.

As shown in the illustration of engineered substrate 602 in FIG. 6C, the eutectic barrier layer 660 can be formed on both sides (i.e., the front side and the back side) as well as the peripheral sides of the conductive layer 614. In one embodiment, the first adhesion layer 612 encapsulates the polycrystalline ceramic core 610, the conductive layer 614 encapsulates the first adhesion layer 612, the eutectic barrier layer 616 encapsulates the conductive layer 614, the second adhesion layer 618 encapsulates the eutectic barrier layer 616, and the diffusion barrier layer 620 encapsulates the second adhesion layer 618.

As shown in the illustration of engineered substrate 603 in FIG. 6D, the eutectic barrier layer 672 can be formed on both sides (i.e., the front side and the back side) of the conductive layer 614, and the eutectic adhesion layer 670 is coupled between the eutectic barrier layer 672 and the conductive layer 614 on both sides (i.e., the front side and the back side) as well as the peripheral sides. In other words, the embodiment shown in FIG. 6D is a combination of those shown in FIGS. 6B and 6C. One of ordinary skill in the art would recognize many variations, modifications, and alternatives.

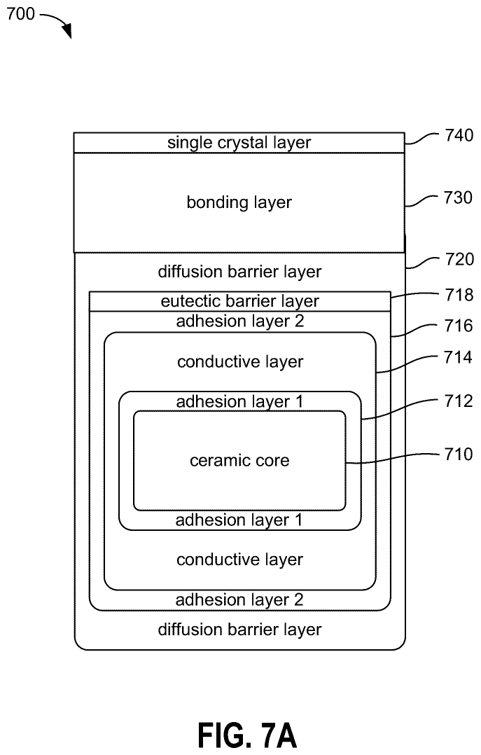

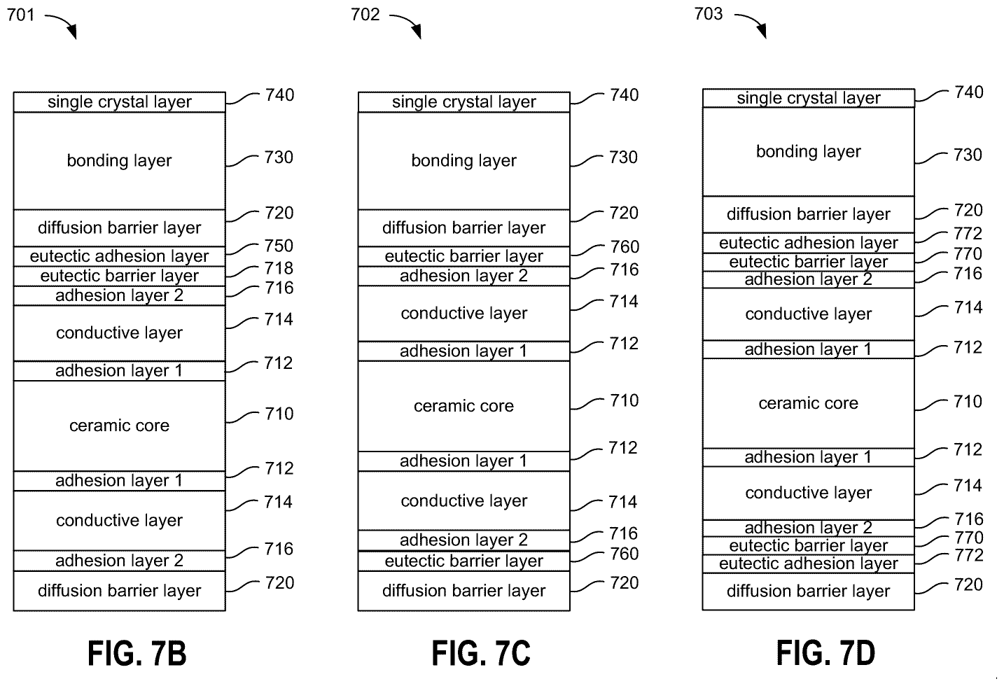

FIG. 7A is a simplified schematic diagram illustrating an engineered substrate structure according to an embodiment of the present invention. FIG. 7B is a simplified schematic diagram illustrating an engineered substrate structure according to another embodiment of the present invention. FIG. 7C is a simplified schematic diagram illustrating an engineered substrate structure according to another embodiment of the present invention. FIG. 7D is a simplified schematic diagram illustrating an engineered substrate structure according to another embodiment of the present invention. The engineered substrate illustrated in FIGS. 7A-7D share common elements with the engineered substrate illustrated in FIGS. 1 and 4A-4D and the discussion provided in relation to the engineered substrate illustrated in FIGS. 1 and 4A-4D is applicable to the engineered substrate illustrated in FIGS. 7A-7D as appropriate.

As shown in FIG. 7A, the engineered substrate 700 includes a polycrystalline ceramic core 710 and a first adhesion layer 712 coupled to the polycrystalline ceramic core 710. The engineered substrate 700 also includes a conductive layer 714 coupled to the first adhesion layer 712 and a second adhesion layer 716 coupled to the conductive layer 714. The engineered substrate 700 also includes a eutectic barrier layer 718 coupled to the second adhesion layer 716 and a diffusion barrier layer 720 coupled to the eutectic barrier layer 718. The engineered substrate 700 also includes a bonding layer 730 coupled to the diffusion barrier layer 720 and a substantially single crystal layer 740 coupled to the bonding layer 730. The engineered substrate may also include an epitaxial III-V layer coupled to the substantially single crystal layer.

As shown in the illustration of engineered substrate 701 in FIG. 7B, a eutectic adhesion layer 750 is coupled between the eutectic barrier layer 718 and the diffusion barrier layer 720. The eutectic adhesion layer 750 can facilitate the coupling between the eutectic barrier layer 718 and the diffusion barrier layer 720.

As shown in the illustration of engineered substrate 702 in FIG. 7C, the eutectic barrier layer 760 can be formed on both sides (i.e., the front side and the back side) as well as the peripheral sides of the second adhesion layer 716. In one embodiment, the first adhesion layer 712 encapsulates the polycrystalline ceramic core 710, the conductive layer 714 encapsulates the first adhesion layer 712, the second adhesion layer 716 encapsulates the conductive layer 714, the eutectic barrier layer 760 encapsulates the second adhesion layer 716, and the diffusion barrier layer 720 encapsulates the eutectic barrier layer 760.

As shown in the illustration of engineered substrate 703 in FIG. 7D, the eutectic barrier layer 772 can be formed on both sides (i.e., the front side and the back side) as well as the peripheral sides of the second adhesion layer 716, and the eutectic adhesion layer 770 is coupled between the eutectic barrier layer 772 and the diffusion barrier layer 720 on both sides (i.e., the front side and the back side) as well as the peripheral sides. In other words, the embodiment shown in FIG. 7D is a combination of those shown in FIGS. 7B and 7C. One of ordinary skill in the art would recognize many variations, modifications, and alternatives.

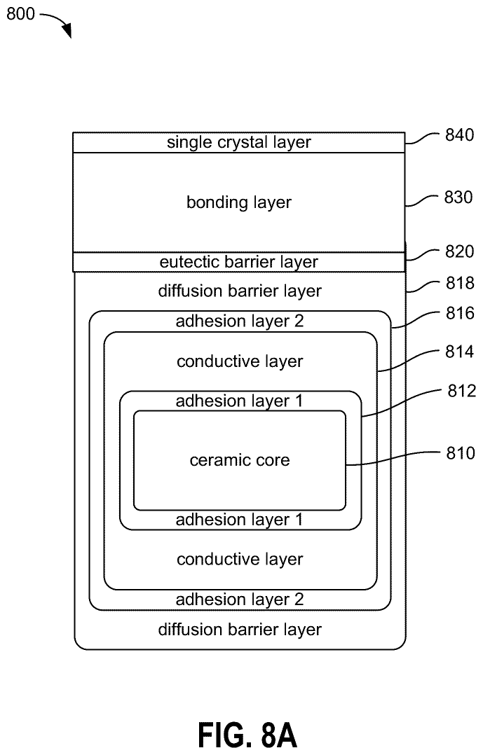

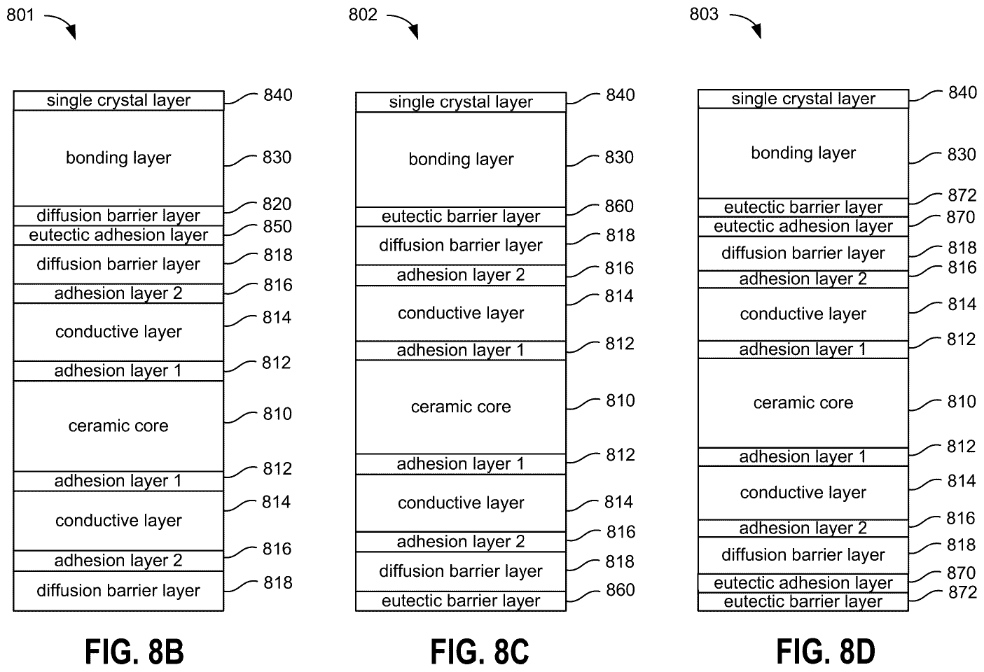

It should be noted that in the embodiments shown in FIGS. 4A-4D, 5A-5D, 6A-6D, and 7A-7D, the eutectic barrier layer is positioned closer to the polycrystalline ceramic core than the diffusion barrier layer. In contrast, as will be discussed below, the embodiments shown in FIGS. 8A-8D differ in that the diffusion barrier layer is positioned closer to the polycrystalline ceramic core than the eutectic barrier layer.

FIG. 8A is a simplified schematic diagram illustrating an engineered substrate structure according to an embodiment of the present invention. FIG. 8B is a simplified schematic diagram illustrating an engineered substrate structure according to another embodiment of the present invention. FIG. 8C is a simplified schematic diagram illustrating an engineered substrate structure according to another embodiment of the present invention. FIG. 8D is a simplified schematic diagram illustrating an engineered substrate structure according to another embodiment of the present invention. The engineered substrate illustrated in FIGS. 8A-8D share common elements with the engineered substrate illustrated in FIGS. 1 and 4A-4D and the discussion provided in relation to the engineered substrate illustrated in FIGS. 1 and 4A-4D is applicable to the engineered substrate illustrated in FIGS. 8A-8D as appropriate.

As shown in FIG. 8A, the engineered substrate 800 includes a polycrystalline ceramic core 810 and a first adhesion layer 812 coupled to the polycrystalline ceramic core 810. The engineered substrate 800 also includes a conductive layer 814 coupled to the first adhesion layer 812 and a second adhesion layer 816 coupled to the conductive layer 814. The engineered substrate 800 also includes a diffusion barrier layer 818 coupled to the second adhesion layer 816 and a eutectic barrier layer 820 coupled to the diffusion barrier layer 818. The engineered substrate 800 also includes bonding layer 830 coupled to the eutectic barrier layer 820 and a substantially single crystal 840 coupled to the bonding layer 830. The engineered substrate may also include an epitaxial III-V layer coupled to the substantially single crystal layer.

As shown in the illustration of engineered substrate 801 in FIG. 8B, a eutectic adhesion layer 850 is coupled between the eutectic barrier layer 820 and the diffusion barrier layer 818. The eutectic adhesion layer 850 can facilitate the coupling between the eutectic barrier layer 820 and the diffusion barrier layer 818.

As shown in the illustration of engineered substrate 802 in FIG. 8C, the eutectic barrier layer 860 can be formed on both sides (i.e., the front side and the back side) as well as the peripheral surfaces of the diffusion barrier layer 818. In one embodiment, the first adhesion layer 812 encapsulates the polycrystalline ceramic core 810, the conductive layer 814 encapsulates the first adhesion layer 812, the second adhesion layer 816 encapsulates the conductive layer 814, the diffusion barrier layer 818 encapsulates the second adhesion layer 816, and the eutectic barrier layer 820 encapsulates the diffusion barrier layer 818.

As shown in the illustration of engineered substrate 803 in FIG. 8D, the eutectic barrier layer 872 can be formed on both sides (i.e., the front side and the back side) as well as the peripheral surfaces of the diffusion barrier layer 872, and the eutectic adhesion layer 870 is coupled between the eutectic barrier layer 872 and the diffusion barrier layer 818 on both sides (i.e., the front side and the back side) as well as the peripheral sides. In other words, the embodiment shown in FIG. 8D is a combination of those shown in FIGS. 8B and 8C. One of ordinary skill in the art would recognize many variations, modifications, and alternatives.

As discussed above, adding the eutectic barrier layer is not a mere rearrangement or duplication of the diffusion barrier layer. The eutectic barrier prevents the yttria migration at elevated temperatures because eutectic consumption is contained. In contrast, the atomic or molecular diffusion of elements (e.g., yttrium) is prevented by the diffusion barrier layer.

The positions of the eutectic barrier layer and the diffusion barrier layer impact the

structures of the engineered substrate after, for example, an ion implantation process or an anneal process characterized by an elevated temperature. In the embodiment shown in FIG. 4A, the eutectic barrier layer prevents yttria migration, and the yttrium-based compound structure 305 shown in FIG. 3 is not present in the engineered substrate 400 shown in FIG. 4A even at the elevated temperature. In contrast, in the embodiment shown in FIG. 8A, the yttrium-based compound structure 305 shown in FIG. 3 could be present in the engineered substrate 800 shown in FIG. 8A at the elevated temperature. The yttrium-based compound structure 305 may consume a portion of the first adhesion layer 812, the conductive layer 814, the second adhesion layer 816, or even the diffusion barrier layer 818 at the elevated temperature, until the yttria migration is stopped by the eutectic barrier layer 820. Thus, the position of the eutectic barrier layer impacts the structures and physical properties of the engineered substrate after exposure to elevated temperatures.

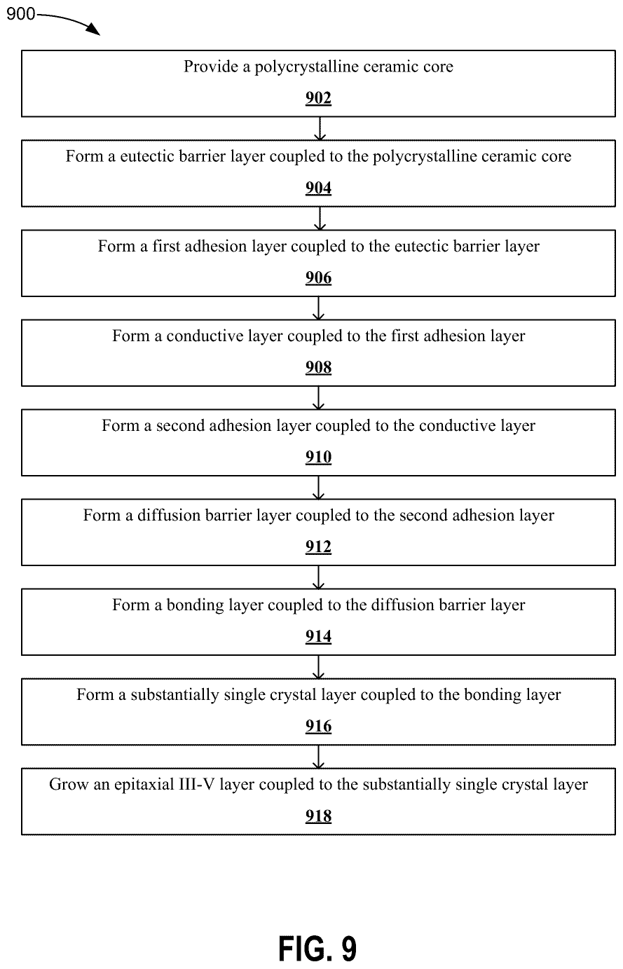

FIG. 9 is a diagram illustrating a simplified flowchart illustrating a method of fabricating an engineered substrate structure according to an embodiment of the present invention. The method 900 includes providing a polycrystalline ceramic core (902) and forming a eutectic barrier layer coupled to the polycrystalline ceramic core (904). The method 900 also includes forming a first adhesion layer coupled to the eutectic barrier (906) layer and forming a conductive layer coupled to the first adhesion layer (908). The method 900 also includes forming a second adhesion layer coupled to the conductive layer (910) and forming a diffusion barrier layer coupled to the second adhesion layer (912). The method 900 also includes forming a bonding layer coupled to the diffusion barrier layer (914) and forming a substantially single crystal layer coupled to the bonding layer (916). The method 900 may also include growing an epitaxial III-V layer coupled to the substantially single crystal layer (918).

It should be appreciated that the specific steps illustrated in FIG. 9 provide a particular method of fabricating a multi-core engineered substrate structure according to an embodiment of the present invention. Other sequences of steps may also be performed according to alternative embodiments. For example, alternative embodiments of the present invention may perform the steps outlined above in a different order. Moreover, the individual steps illustrated in FIG. 9 may include multiple sub-steps that may be performed in various sequences as appropriate to the individual step. Furthermore, additional steps may be added or removed depending on the particular applications. One of ordinary skill in the art would recognize many variations, modifications, and alternatives.

The method 900 can be used to fabricate the engineered substrate shown in FIG. 4A. Similar methods can be used to fabricate the engineered substrate shown in FIGS. 4B-4D. Similar methods can be used to fabricate the engineered substrate shown in FIGS. 5A-5D, 6A-6D, 7A-7D, and 8A-8D. One of ordinary skill in the art would recognize many variations, modifications, and alternatives.

The inventors have appreciated a number of challenges associated with the engineered substrates in relation to interaction between single crystal layers of the engineered substrates and the epitaxial layers coupled to the single crystal layers. In particular, where defects are formed in the single crystal layers that are not sufficiently sealed from the epitaxial materials used during the formation of the device layers, the device layers can interact in an undesirable manner with the exposed single crystal layer, thereby leading to undesirable eutectic growth and delamination of one or more layers of the engineered substrate.

As an example, during fabrication processes for semiconductor structures formed, for example, in device layers on the engineered substrate, the engineered substrate may include a single crystal layer suitable for use as a growth layer during an epitaxial growth process for the formation of the device layers. In particular, a single crystal layer can include a substantially single crystal silicon layer that is attached to a silicon oxide layer using a layer transfer process. During the layer transfer process, it is possible that defects can be formed in the substantially single crystal silicon layer as a result of the fabrication processes, including cracks in the single crystal silicon layer, missing crystal grains, or gaps formed at the edge(s) of the engineered substrate.

After the single crystal layer (e.g., a substantially single crystal silicon layer) is formed, epitaxial layers, including epitaxial buffer layers, can be formed on the single crystal layer. However, given the defects formed in the single crystal layer, the epitaxial buffer layers are not able to fully and conformally cover the single crystal layer. As such, some areas of the single crystal layer that are exposed (e.g., at the defects) may interact with the epitaxial layers as the device layers are formed. Then, and as part of the fabrication processes, the engineered substrate may experience elevated temperatures (e.g., 1300° C.) in processes such as annealing, ion implantation, and the like. At these elevated temperatures, interaction between the exposed portions of the single crystal layer and the epitaxial layers can cause an undesirable eutectic growth and delamination of one or more layers of the engineered substrate. This eutectic growth can lead to delamination of the device layers, thereby significantly reducing the yield of semiconductor devices fabricated on the engineered substrate.

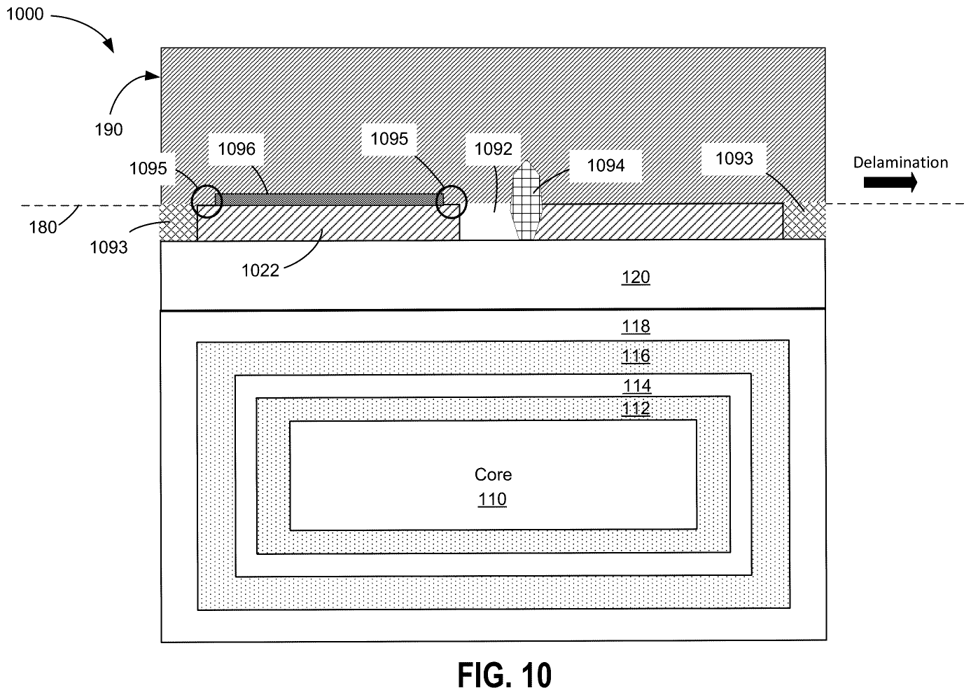

FIG. 10 is a simplified schematic diagram illustrating an engineered substrate 1000 with eutectic growth defects according to an embodiment of the present invention. As mentioned previously in relation to FIG. 1, the defective single crystal layer 1022 formed on the bonding layer 120 is characterized by defect 1092, illustrated as a missing grain, and defects 1093, illustrated as defects formed around the edge(s) of the engineered substrate (e.g., as a result of fabrication processes). Defect 1092 can be formed by cracks in the single crystalline layer 122 illustrated in FIG. 1, missing crystal grains in the defective single crystal layer 1022 as illustrated by defect 1092 in FIG. 10, or defects 1093 formed around the edge(s) of the engineered substrate. Thus, as shown in FIG. 10, the defective single crystal layer 1022, also referred to as a substantially single crystal layer can be a perforated substantially single crystal structure, with the perforations illustrated by defect 1092 exposing the bonding layer 120. In contrast with some single crystal layers, the defective single crystal layer 1022 is discontinuous due to the presence of defect 1092 that exposes the underlying bonding layer 120.

At elevated temperatures, interaction between exposed portions of the defective single crystal layer 1022 and the epitaxial layers of the device layers 190 can cause an undesirable eutectic growth structure 1094 to form at the interaction region 1095 of the exposed portions of the defective single crystal layer 1022 and the device layers 190. The eutectic growth structure 1094 can lead to delamination of one or more of the device layers, thereby significantly reducing the yield of semiconductor devices fabricated on the engineered substrate.

As shown in FIG. 10, a defect 1092 can be formed in a portion of the defective single crystal layer 1022 of the engineered substrate 1000. FIG. 10 is not drawn to scale and the defects are drawn larger in size for ease in understanding. In some examples, the defects 1092 formed in the defective single crystal layer 1022, for example, a missing grain, can have a width in the range of 20 μm to 40 μm. However, in other examples, the defects 1092 may be larger or smaller. In the case where the defects 1092 are formed by cracks in the defective single crystal layer 1022, the defect 1092 may be smaller. Additionally, the size of the defects may be larger as in the case were the defects 1093 are formed around the edge(s) of the engineered substrate (e.g., as a result of fabrication processes), as illustrated in FIG. 10, for example.

As described in relation to FIG. 1, the defective single crystal layer 1022 may be used as a growth layer during an epitaxial growth process for the formation of the device layers 190. In some embodiments, an epitaxial buffer layer 1096 can be formed on defective single crystal layer 1022. In some embodiments, the epitaxial buffer layer 1096 can include AlN and can be formed using MOCVD techniques. After forming the epitaxial buffer layer 1096, a further epitaxial growth process can be used to form the device layers 190. In some embodiments, the device layers 190 include an epitaxial material layer. In one example, the epitaxial material layer includes a GaN layer 2 μm to 10 μm in thickness, which can be utilized as one of a plurality of layers utilized in optoelectronic devices, RF devices, power devices, and the like.

However, the inventors have determined that the epitaxial buffer layer 1096 formed from the AlN MOCVD process may not fully and conformally cover the defective single crystal layer 1022. As shown in FIG. 10, at interaction regions 1095, the exposed portions of the defective single crystal layer 1022 contact the device layers 190 (e.g., the GaN). As a result, at high temperatures associated with the epitaxial growth process (e.g., temperatures greater than 1100° C., for example, on the order of 1200° C. or 1300° C.) the exposed defect portions of the defective single crystal layer 1022 in interaction regions 1095 interact with the epitaxial material layers that form the device layers 190. As shown in FIG. 10, interaction between the defective single crystal layer 1022 and the device layers 190 at the interaction regions 1095 can lead to the formation of undesirable eutectic growth structures 1094 (e.g., a silicon rich eutectic growth) on the engineered substrate 1000 that adversely deteriorates the defective single crystal layer 1022. For example, at elevated temperatures, the GaN that is grown as part of the epitaxial growth processes to form the device layers 190 may be liquified due to the high processing temperatures.

The liquified GaN may interact with the exposed portions of the defective single crystal layer 1022 and consume the exposed portions of the defective single crystal layer 1022 (i.e., consume the silicon material) thereby leading to the formation of eutectic growth structure 1094 and delamination of the device layers 190.

To address the undesirable growth of eutectic growth structure 1094, embodiments of

the present invention provide an engineered substrate that includes a eutectic barrier layer formed on the defective single crystal layer 1022 before the growth of the epitaxial material layers that form device layers 190. The inventors have determined that utilizing a eutectic barrier layer, such as one or more layers including AlN formed on the defective single crystal layer 1022 using atomic layer deposition (ALD), can result in covering and sealing of defects 1092 and defects 1093 present in the defective single crystal layer 1022. After forming the eutectic barrier layer, a planarization layer can be formed on top of the eutectic barrier layer. This planarization layer can be formed using an oxide or nitride material. After forming the eutectic barrier layer and the planarization layer, the engineered substrate 1000 can undergo a chemical mechanical polishing (CMP) process to remove excess portions of the eutectic barrier layer and planarization layers, thereby exposing portions of the defective single crystal layer 1022, but with defects 1092 and defects 1093 completely sealed. This process prepares the engineered substrate 1000 for the epitaxial growth processes utilized to form the device layers 190.

Importantly, adding the eutectic barrier layer formed on top of the defective single crystal layer 1022 is not a mere rearrangement of layers or duplication of a barrier layer. Although the eutectic barrier layer functions as a barrier to prevent interaction between the defective single crystal layer 1022 and the device layers, the presence of the eutectic barrier layer in the engineered substrate is not merely the diffusion barrier layer 118 illustrated in FIG. 1 being shifted to a different position in the engineered substrate structure. In fact, and similar to the eutectic barrier layer discussed in relation to FIG. 3, the eutectic barrier layer and the diffusion barrier layer have different principles of operation and function as barriers at different temperature ranges.

Moreover, the eutectic barrier layer modifies the physical structure of the engineered substrate. The inventors have determined that the introduction of the eutectic barrier layer formed on the defective single crystal layer 1022 produces the unexpected result of preventing interaction between the exposed portions of the defective single crystal layer 1022 and the device layers even though this was not prevented by the existing diffusion barrier. Therefore, the functionality of the eutectic barrier layer included in the engineered substrate was not expected until discovered by the inventors. Although some embodiments of the present invention are discussed in relation to formation or growth of a layer, embodiments of the present invention are not limited to a single layer of a single material. It should be appreciated that reference to a layer includes formation of multiple sub-layers. One of ordinary skill in the art would recognize many variations, modifications, and alternatives.

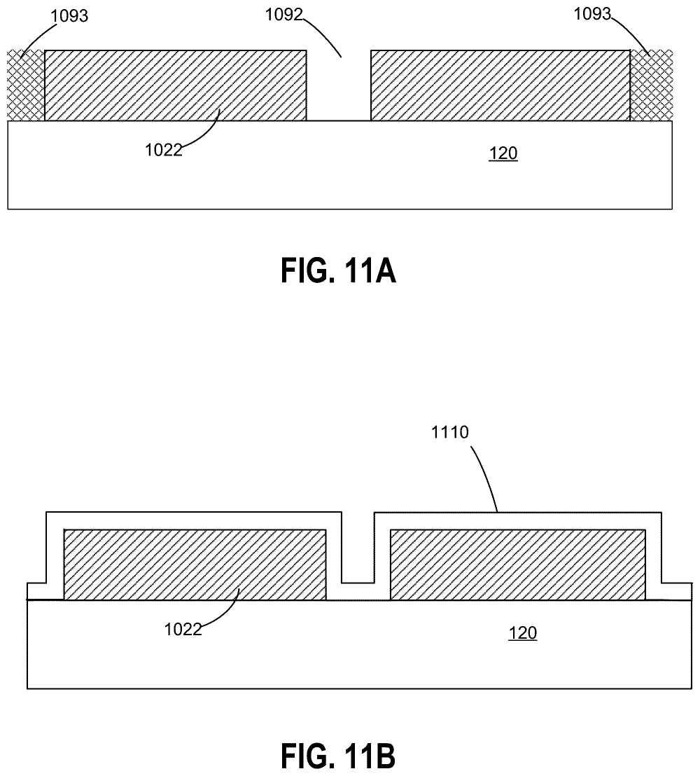

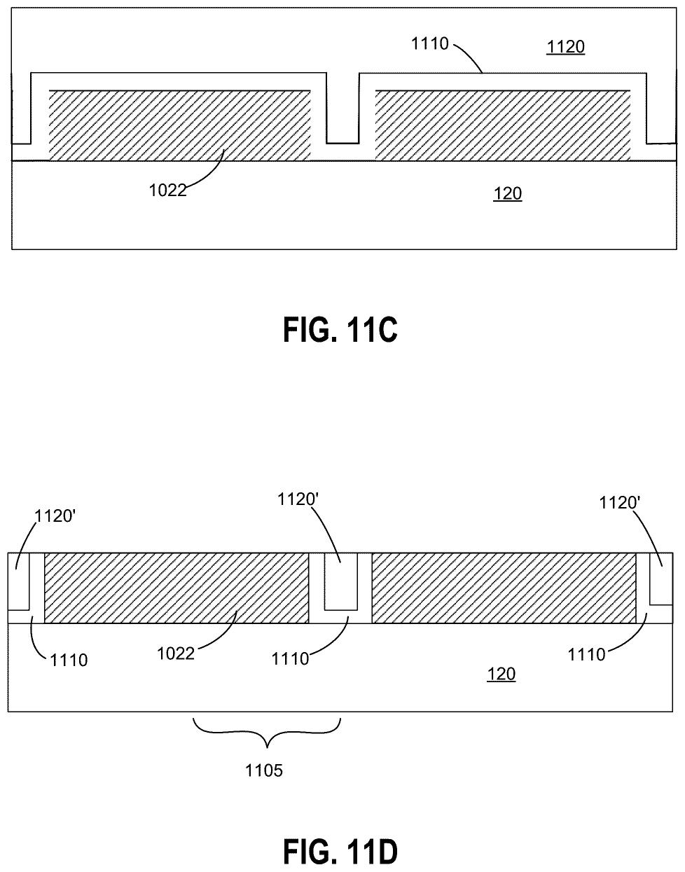

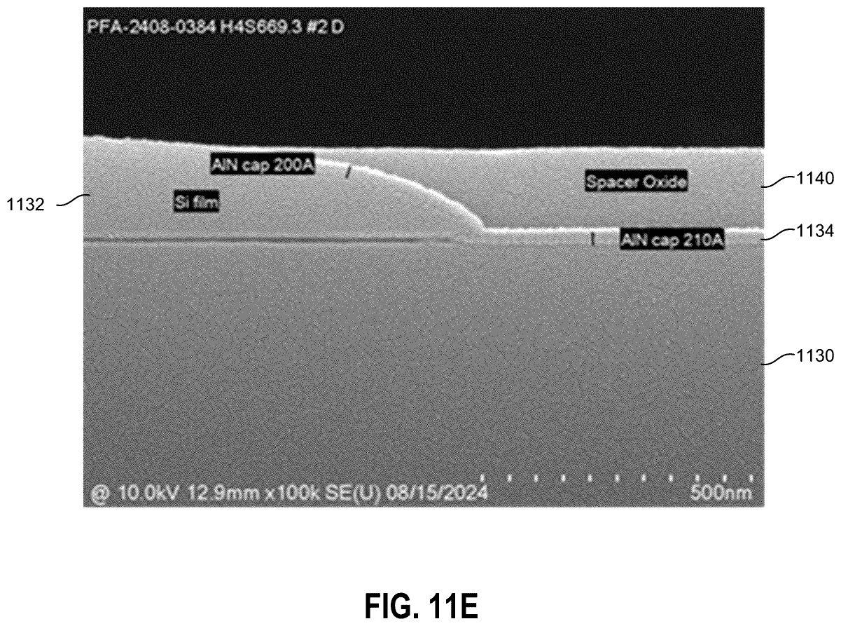

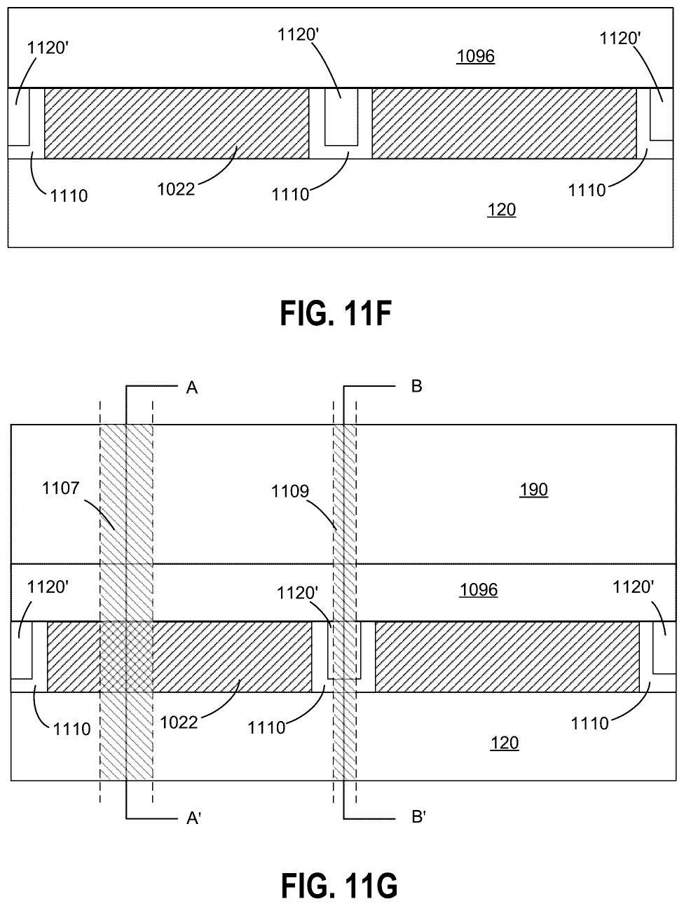

FIG. 11A is a simplified schematic diagram illustrating a semiconductor device with defects formed in the substantially single crystal layer according to an embodiment of the present invention. FIG. 11A shows a portion of the engineered substrate 1000 described in relation to FIG. 10 and includes the bonding layer 120 and the defective single crystal layer 1022. As shown in FIG. 11A, the engineered substrate also includes defect 1092 and defects 1093 formed in the defective single crystal layer 1022. As described more fully above in relation to FIG. 10, defect 1092 and defects 1093 may be formed in the defective single crystal layer 1022 before the growth of the epitaxial material layers that form the device layers 190 illustrated in FIG. 10. The defect 1092 and defects 1093 may form due to imperfections in the defective single crystal layer 1022 such as by cracks, missing crystal grains, or gaps formed around the edge(s) of the engineered substrate.

FIG. 11B is a simplified schematic diagram illustrating a semiconductor device with a eutectic barrier layer according to an embodiment of the present invention. As shown in FIG. 11B, before device layers 190 are formed on the defective single crystal layer 1022, a eutectic barrier layer 1110 may be deposited on the defective single crystal layer 1022. The eutectic barrier layer 1110 may be a conformal coating, such as a conformal layer of AlN, formed on the defective single crystal layer 1022 by techniques utilizing ALD to thereby form an ALD AlN eutectic barrier layer. The eutectic barrier layer 1110 may be deposited across the entire defective single crystal layer 1022 to fully and conformally cover the defective single crystal layer 1022, including all defects including defect 1092 and defects 1093. In some embodiments, the eutectic barrier layer 1110 may be 100 Å to 200 Å in thickness.

FIG. 11C is a simplified schematic diagram illustrating a semiconductor device with a planarization layer according to an embodiment of the present invention. As shown in FIG. 11C, after the eutectic barrier layer 1110 is deposited on the defective single crystal layer 1022, a planarization layer 1120 can be formed on the eutectic barrier layer 1110. The planarization layer 1120 can fill all the remaining voids in the engineered substrate 1000 that may still be present after depositing the eutectic barrier layer 1110. For example, because the eutectic barrier layer 1110 can have a thickness between 100 Å to 200 Å, which is not as thick as the defective single crystal layer 1022 (e.g., because the defective single crystal layer 1022 can have a thickness on the order of 0.5 μm), there may still be voids present in the defective single crystal layer 1022. Accordingly, the planarization layer 1120 can be deposited on the eutectic barrier layer 1110 to fill the voids in the defective single crystal layer and bring the front surface of the engineered substrate 1000 to a uniform height. In some embodiments, the planarization layer 1120 may be an oxide material and may have a thickness varying from 100 Å to 2,000 Å, depending on the size of the defect 1092 and defects 1093 as well as the particular application.

FIG. 11D is a simplified schematic diagram illustrating a semiconductor device after a CMP process according to an embodiment of the present invention. After the eutectic barrier layer 1110 and planarization layer 1120 are formed on the defective single crystal layer 1022, a CMP process may be utilized to expose the defective single crystal layer 1022 with the defect 1092 and defects 1093 sealed off by the eutectic barrier layer 1110. Utilizing a CMP process can planarize the planarization layer 1120, thereby forming planarized structures 1120′ that are level with the exposed front surface of the defective single crystal layer 1022. A CMP process may smooth out the surface of the defective single crystal layer 1022 to prepare the engineered substrate for the epitaxial growth processes to form device layers 190. Additionally, since defect 1092 and defects 1093 are sealed off, interaction between the exposed portions of defective single crystal layer 1022 (e.g., at interaction region 1095 described in relation to FIG. 10) and the epitaxial layers that form the device layers 190 is eliminated or reduced. The reduction or elimination in interaction prevents the undesirable eutectic growth structure 1094 illustrated in FIG. 10 from forming, thereby improving the yield of semiconductor devices fabricated on the engineered substrate.

Although not illustrated in FIG. 11D for purposes of clarity, slight dishing of the planarized structure 1120′ can be present. The inventors have determined that utilizing a smooth profile of the edges formed at the interaction region 1095 between the defective single crystal layer 1022 and the defect 1092 and defects 1093 is desirable and improves the yield and performance of semiconductor devices fabricated on the engineered substrate. As such, in some examples, the profile of the eutectic barrier layer 1110 and the planarized structures 1120′ are smoothed out (e.g., not rigid or sharp) after the CMP process.

FIG. 11E is a scanning electron microscope image of the semiconductor device after the CMP process illustrated in FIG. 11D. As illustrated in FIG. 11E, a silicon film 1132 and a AlN cap 1134 are disposed on a silicon oxide layer 1130. The thickness of the AlN cap 1134 is ˜200 Å, resulting in a thickness measurement of 210 A under the spacer oxide and a thickness measurement of 200 Å on the sloped side of the silicon film. A spacer oxide 1140 is formed in a gap in the silicon film 1132. Referring to region 1105 shown in FIG. 11D and FIG. 11E, the silicon oxide layer 1130 corresponds to the bonding layer 120, the silicon film 1132 corresponds to the defective single crystal layer 1022, the AlN cap 1134 corresponds to the eutectic barrier layer 1110, and the spacer oxide 1140 corresponds to planarized structures 1120′.

FIG. 11F is a simplified schematic diagram illustrating a semiconductor device with an epitaxial buffer layer according to embodiment of the present invention. After the CMP process described in relation to FIG. 11D and illustrated in FIG. 11E, an epitaxial buffer layer 1096 can be formed on the defective single crystal layer 1022, the exposed portions of the eutectic barrier layer 1110, and the planarized structure 1120′. The epitaxial buffer layer 1096 can comprise an AlN material deposited using MOCVD techniques as described in relation to FIG. 10.

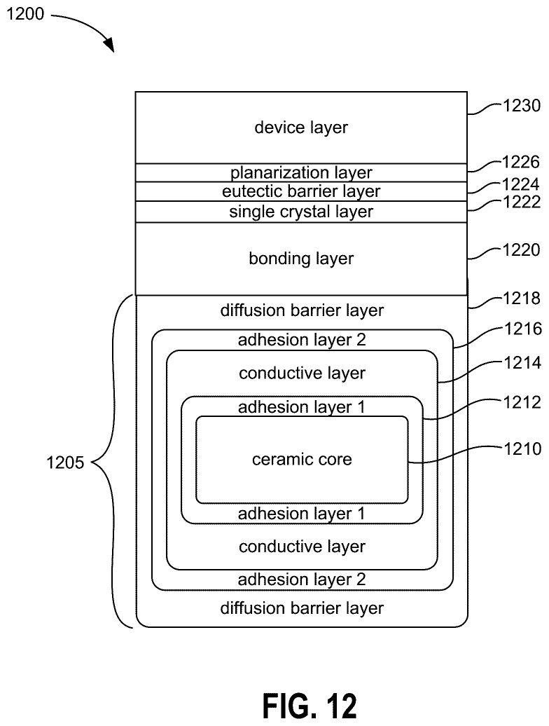

FIG. 11G is a simplified schematic diagram illustrating a semiconductor device according to embodiment of the present invention. As illustrated in FIG. 11G, deposition of the epitaxial buffer layer 1096 may be followed by the epitaxial growth of the device layers 190. The epitaxial growth process used to form the epitaxial buffer layer 1096 and the device layers 190 are discussed in more detail in relation to FIG. 1 above and FIG. 12 below. Although epitaxial buffer layer 1096 is illustrated as a single ALD AlN layer in FIG. 11G, this is not required by embodiments of the present invention. In other embodiments, epitaxial buffer layer 1096 can include ALD AlN/AlGaN/GaN. One of ordinary skill in the art would recognize many variations, modifications, and alternatives.

Referring to FIG. 11G, a first region 1107 of the engineered substrate corresponding to cross-section A-A′ includes the device layers 190, for example, an epitaxial III-V layer or a plurality of epitaxial III-V layers coupled to the substantially single crystal layer 1022. In other embodiments, other epitaxial layers are utilized to form the device layers 190. In the embodiment illustrated in FIG. 11G, the epitaxial buffer layer 1096 is disposed between the substantially single crystal layer 1022 and the device layers 190.

A second region 1109 of the engineered substrate corresponding to cross-section B-B′ includes a eutectic barrier layer 1110 coupled to the bonding layer 120 and a planarized structure 1120′ coupled to the eutectic barrier layer. The second region 1109 also includes the device layers 190, e.g., one or more epitaxial III-V layers, coupled to the planarization structure 1120′.

Thus, after the CMP process is used to expose the defective single crystal layer 1022 in region 1107, defects in the defective single crystal layer 1022 are sealed off by the eutectic barrier layer 1110 and the planarized structure 1120′, resulting in a structure that is level with the exposed front surface of the defective single crystal layer 1022. Deposition of the epitaxial buffer layer 1096 and the device layers 190 can then be performed. Since defects are sealed off, interaction between the otherwise exposed portions of defective single crystal layer 1022 and the epitaxial layers that form the device layers 190 is eliminated or reduced, thereby preventing the undesirable eutectic growth structure 1094 illustrated in FIG. 10 from forming and improving the yield of semiconductor devices fabricated on the engineered substrate.

FIG. 12 is a simplified schematic diagram illustrating an engineered substrate structure 1200 according to an embodiment of the present invention. As shown in FIG. 12, the engineered substrate structure 1200 includes a polycrystalline ceramic core 1210. The engineered substrate structure 1200 also includes a first adhesion layer 1212 coupled to the polycrystalline ceramic core 1210 and a conductive layer 1214 coupled to the first adhesion layer 1212. The engineered substrate structure 1200 also includes a second adhesion layer 1216 coupled to the conductive layer 1214 and a diffusion barrier layer 1218 coupled to the second adhesion layer 1216. The engineered substrate structure 1200 also includes a bonding layer 1220 coupled to the diffusion barrier layer 1218 and a substantially single crystal layer 1222 coupled to the bonding layer 1220. The engineered substrate structure 1200 also includes a eutectic barrier layer 1224 coupled to substantially single crystal layer 1222 and a planarization layer 1226 coupled to the eutectic barrier layer 1224. The engineered substrate structure 1200 also includes an epitaxial III-V layer 1230 coupled to the planarization layer 1226.

In some embodiments, the epitaxial III-V layer 1230 is an epitaxial GaN layer or GaN-based layer, and the substantially single crystalline layer 1222 comprises a silicon (111) layer. In other embodiments, the substantially single crystalline layer 1222 can include, for example, SiC, sapphire, GaN, AlN, SiGe, Ge, diamond, Ga₂O₃, AlGaN, InGaN, InN, and/or ZnO. In some embodiments, the substantially single crystal layer 1222 can have a thickness from 0 to 0.5 μm. The substantially single crystal layer 1222 is suitable for use as a growth layer during an epitaxial growth process for the formation of epitaxial material thereon. The crystalline layers of the epitaxial material are an extension of the underlying semiconductor lattice associated with the substantially single crystal layer. The unique CTE matching properties of the engineered substrate structure 1200 enable growth of thicker epitaxial material than existing technologies.

Moreover, as discussed above, the eutectic barrier layer 1224 coupled to the substantially single crystal layer 1222 can seal all defects present in the substantially single crystal layer 1222 to prepare the substantially single crystal layer 1222 for the epitaxial growth processes. Sealing the substantially single crystal layer 1222 reduces or eliminates interaction between the epitaxial growth layers (e.g., the device layers) from harmful interaction with the exposed portions of the substantially single crystal layer 1222 that can result in undesirable eutectic growth structures and delamination. The eutectic barrier layer 1224 can include an AlN material deposited on the substantially single crystalline layer 1222 using atomic layer deposition (ALD). After forming the eutectic barrier layer 1224, a planarization layer 1226 can be formed on top of the eutectic barrier layer 1224. The planarization layer 1226 can be formed of an oxide material suitable to be followed by a CMP process to smooth the surface of the engineered substrate structure 1200 to prepare it for the epitaxial growth processes.

In addition, although the embodiment shown in FIG. 12 has been illustrated with various layers 1210, a person of ordinary skill in the art would appreciate that one or more of these layers 1210 may be optional, depending on the particular structure and/or fabrication process. By way of example, in some cases, if the diffusion barrier layer 1218 (which typically includes silicon nitride) is suitable for being deposited directly on the conductive layer (which typically includes polysilicon), the second adhesion layer 1216 can be omitted. Therefore, one or more of these layers may be optional, depending on the particular structure and/or fabrication process.

Additionally, and as shown in FIG. 12, the various layers making up layer stack 1205 may be formed as encapsulation layers. Referring to FIG. 12, the polycrystalline ceramic core 1210 may be fully encapsulated by the first adhesion layer 1212. The first adhesion layer 1212 may be fully encapsulated by the conductive layer 1214 and the conductive layer 1214 may be fully encapsulated by the second adhesion layer 1216. Moreover, the second adhesion layer 1216 may be fully encapsulated by the diffusion barrier layer 1218. Thus, the simplified schematic diagram illustrated in FIG. 12 is merely a cross-section of a portion of the engineered substrate structure as will be evident to one of skill in the art. Since this cross-sectional view only illustrates encapsulation in the plane of the figure, it will be appreciated that the peripheral surfaces of the various layers will also be encapsulated in the planes behind and in front of the plane of the figure. One of ordinary skill in the art would recognize many variations, modifications, and alternatives.

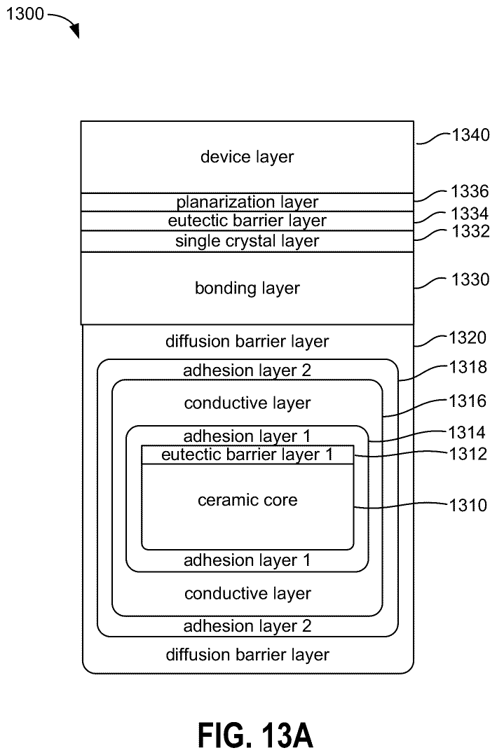

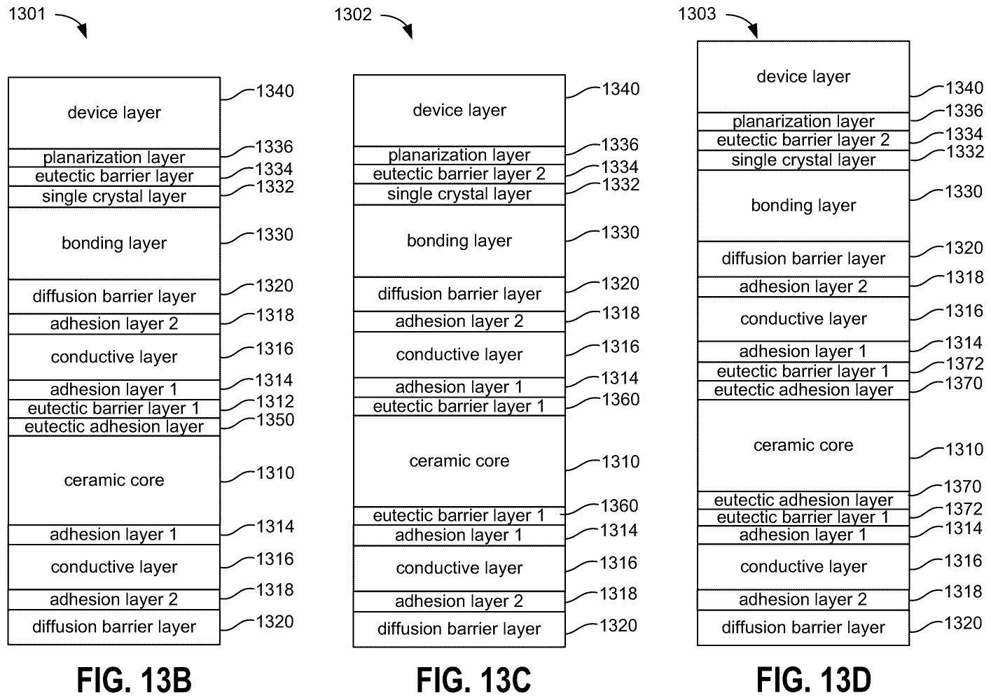

FIG. 13A is a simplified schematic diagram illustrating an engineered substrate structure according to an embodiment of the present invention. FIG. 13B is a simplified schematic diagram illustrating an engineered substrate structure according to another embodiment of the present invention. FIG. 13C is a simplified schematic diagram illustrating an engineered substrate structure according to another embodiment of the present invention. FIG. 13D is a simplified schematic diagram illustrating an engineered substrate structure according to another embodiment of the present invention. The engineered substrate illustrated in FIGS. 13A-13D share common elements with the engineered substrate illustrated in FIG. 1, FIG. 3, FIG. 4A-4D, FIG. 5A-5D, FIG. 6A-6D, FIG. 7A-7D, and FIG. 8A-8D and the discussion provided in relation to the engineered substrate illustrated in FIG. 1 is applicable to the engineered substrate illustrated in FIGS. 13A-13D as appropriate.

As shown in FIG. 13A, the engineered substrate 1300 includes a polycrystalline ceramic core 1310 and a first eutectic barrier layer 1312 coupled to the polycrystalline ceramic core 1310. The engineered substrate 1300 also includes a first adhesion layer 1314 coupled to the first eutectic barrier layer 1312 and a conductive layer 1316 coupled to the first adhesion layer 1314. The engineered substrate 1300 also includes a second adhesion layer 1318 coupled to the conductive layer 1316 and a diffusion barrier layer 1320 coupled to the second adhesion layer 1318. The engineered substrate 1300 also includes a bonding layer 1330 coupled to the diffusion barrier layer 1320 and a substantially single crystal layer 1332 coupled to the bonding layer 1330. The engineered substrate 1300 also includes a second eutectic barrier layer 1334 coupled to the single crystal layer 1332 and a planarization layer 1336 coupled to the second eutectic barrier layer 1334. The engineered substrate 1300 also includes a device layer 1340 coupled to the planarization layer 1336.

Additionally, as discussed above, the first eutectic barrier layer 1312 can prevent the migration of yttrium-based compounds caused by the eutectic mixture from reaching the bonding layer 1330. The first eutectic barrier layer 1312 may also serve to prevent the atomic or molecular diffusion of elements such as yttrium like from migrating to the diffusion barrier layer 1320, as shown in FIG. 2C. To some extent, the first eutectic barrier layer 1312 may serve as a dual-function barrier layer, constraining both atomic or molecular diffusion and eutectic consumption. In such a case, a diffusion barrier layer positioned farther from the polycrystalline ceramic core than the first eutectic barrier layer 1312 may become optional or redundant. Moreover, as discussed above, the second eutectic barrier layer 1334 can prevent interaction between the exposed portions of the defective single crystal layer and the device layers thereby reducing or eliminating undesirable eutectic growth structures from forming in the engineered substrate when subject to high processing temperatures.

As shown in the illustration of engineered substrate 1301 in FIG. 13B, a eutectic adhesion layer 1350 is coupled between the polycrystalline ceramic core 1310 and the first eutectic barrier layer 1312. The eutectic adhesion layer 1350 can facilitate the coupling between the polycrystalline ceramic core 1310 and the first eutectic barrier layer 1312. The inventors have determined that a thin eutectic adhesion layer at the interface between the first eutectic barrier layer and another layer increases the adhesion strength. In some embodiments, a thin eutectic adhesion layer surrounds the surface of the first eutectic barrier layer. In addition, surface preparation techniques such as cleaning of the surface or plasma activation can improve the adhesion between the first eutectic barrier layer and another layer. Although encapsulation by the first adhesion layer 1314, the conductive layer 1316, the second adhesion layer 1318, and the diffusion barrier layer 1320 is not illustrated in FIG. 13B for purposes of clarity, as well as FIGS. 13C and 13D below, it will be appreciated that encapsulation by these layers is included within the scope of the present invention. One of ordinary skill in the art would recognize many variations, modifications, and alternatives.

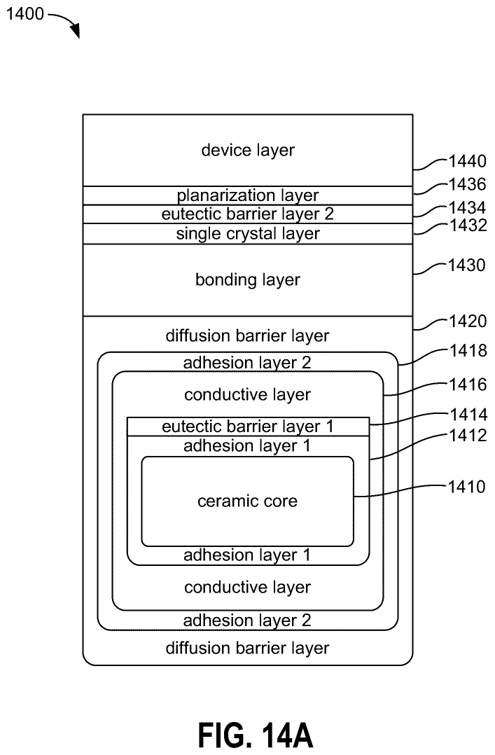

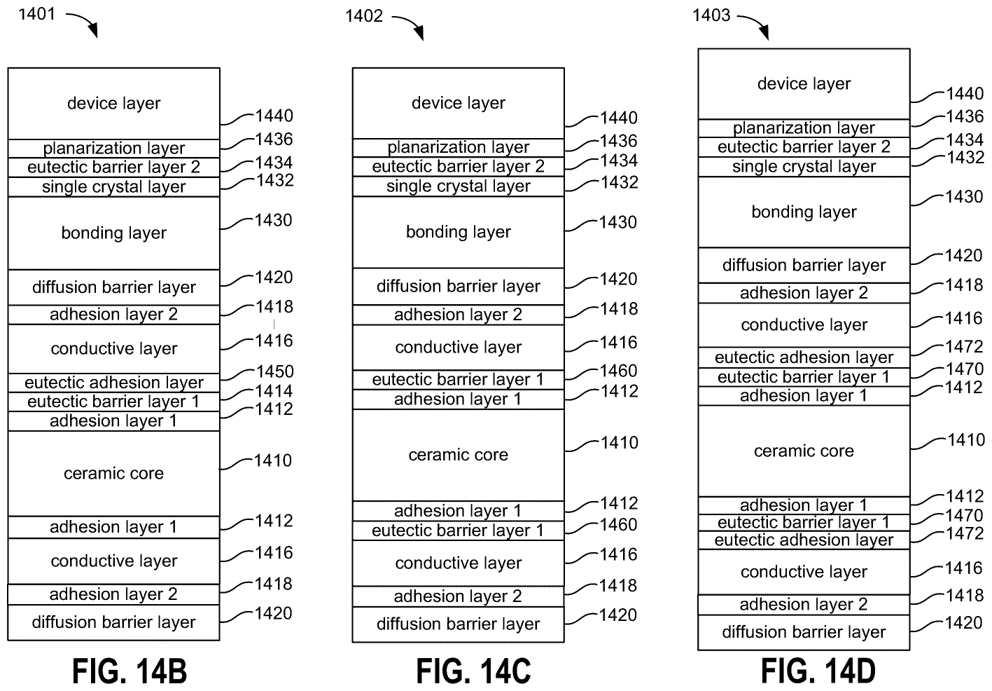

As shown in the illustration of engineered substrate 1302 in FIG. 13C, the first eutectic barrier layer 1360 can be formed on both sides (i.e., the front side and the back side) as well as the peripheral surfaces of the polycrystalline ceramic core 1310. In one embodiment, the first eutectic barrier layer 1360 encapsulates the polycrystalline ceramic core 1310. Not only is the first eutectic barrier layer 1360 coupled to the front surface (the surface facing the device layers 190 shown in FIG. 1) of the polycrystalline ceramic core 1310, but also to the back surface (the surface opposite to the front surface) of the polycrystalline ceramic core 1310, as well as the side or peripheral surface(s) of the polycrystalline ceramic core 1310. Some deposition techniques (e.g., PVD) are particularly well suited for use for single-side deposition, whereas some deposition techniques (e.g., ALD) are particularly well suited for an encapsulating deposition in which both surfaces of the substrate, as well as the sides of the substrate, can be coated. In some implementations, deposition on both surfaces of the substrate and/or an encapsulating deposition can be performed via a single-side deposition followed by flipping the substrate and repeating the single-side deposition process. Moreover, there are other considerations that can be utilized in determining the suitable deposition technique(s) that are used. For example, if ALD is used to deposit the first eutectic barrier layer 1312, this is generally performed after deposition of the conductive layer 1316, e.g., a polysilicon layer. As will be discussed below, this process flow is used in the embodiments shown in FIGS. 14A-14D, 15A-15D, 16A-16D, and 17A-17D. One of ordinary skill in the art would recognize many variations, modifications, and alternatives.

Likewise, in some embodiments, the first adhesion layer 1314 encapsulates the first eutectic barrier layer 1312, the conductive layer 1316 encapsulates the first adhesion layer 1314, the second adhesion layer 1318 encapsulates the conductive layer 1316, and the diffusion barrier layer 1320 encapsulates the second adhesion layer 1318.

As shown in the illustration of engineered substrate 1303 in FIG. 13D, the first eutectic barrier layer 1370 can be formed on both sides (i.e., the front side and the back side) as well as the peripheral sides of the polycrystalline ceramic core 1310, and the eutectic adhesion layer 1372 is coupled between the polycrystalline ceramic core 1310 and the fist eutectic barrier layer 1372 on both sides (i.e., the front side and the back side). In other words, the embodiment shown in FIG. 13D is a combination of those shown in FIGS. 13B and 13C. In some embodiments, in addition to the first eutectic barrier layer 1372 encapsulating the polycrystalline ceramic core 1310, the second eutectic barrier layer 1334 also encapsulates the polycrystalline ceramic core. One of ordinary skill in the art would recognize many variations, modifications, and alternatives.

In some embodiments, the polycrystalline ceramic core comprises AlN, the first adhesion layer comprises a first TEOS-based oxide layer, the conductive layer comprises a polysilicon layer, the second adhesion layer comprises a second TEOS-based oxide layer, the diffusion barrier layer comprises a silicon nitride layer. In some embodiments, the bonding layer comprises an oxide layer formed by PECVD. In some embodiments, the substantially single crystalline layer comprises a silicon (111) layer.

FIG. 14A is a simplified schematic diagram illustrating an engineered substrate structure according to an embodiment of the present invention. FIG. 14B is a simplified schematic diagram illustrating an engineered substrate structure according to another embodiment of the present invention. FIG. 14C is a simplified schematic diagram illustrating an engineered substrate structure according to another embodiment of the present invention. FIG. 14D is a simplified schematic diagram illustrating an engineered substrate structure according to another embodiment of the present invention. The engineered substrate illustrated in FIGS. 14A-14D share common elements with the engineered substrate illustrated in FIGS. 1 and 13A-13D and the discussion provided in relation to the engineered substrate illustrated in FIGS. 1 and 13-13D is applicable to the engineered substrate illustrated in FIGS. 14A-14D as appropriate.

As shown in FIG. 14A, the engineered substrate 1400 includes a polycrystalline ceramic core 1410 and a first adhesion layer 1412 coupled to the polycrystalline ceramic core 1410. The engineered substrate 1400 also includes a first eutectic barrier layer 1414 coupled to the first adhesion layer 1412 and a conductive layer 1416 coupled to the first eutectic barrier layer 1414. The engineered substrate 1400 also includes a second adhesion layer 1418 coupled to the conductive layer 1416 and a diffusion barrier layer 1420 coupled to the second adhesion layer 1418. The engineered substrate 1400 also includes a bonding layer 1430 coupled to the diffusion barrier layer 1420 and a substantially single crystal layer 1432 coupled to the bonding layer 1430. The engineered substrate 1400 also includes a second eutectic barrier layer 1434 coupled to the single crystal layer 1432 and a planarization layer 1436 coupled to the second eutectic barrier layer 1434. The engineered substrate 1400 also includes a device layer 1440 coupled to the planarization layer 1436.

As shown in the illustration of engineered substrate 1401 in FIG. 14B, a eutectic adhesion layer 1450 is coupled between the first eutectic barrier layer 1414 and the conductive layer 1416. The eutectic adhesion layer 1450 can facilitate the coupling between the first eutectic barrier layer 1414 and the conductive layer 1416.

As shown in the illustration of engineered substrate 1402 in FIG. 14C, the first eutectic barrier layer 1460 can be formed on both sides (i.e., the front side and the back side) as well as the peripheral sides of the first adhesion layer 1412. In one embodiment, the first adhesion layer 1412 encapsulates the polycrystalline ceramic core 1410, the first eutectic barrier layer 1414 encapsulates the first adhesion layer 1412, the conductive layer 1416 encapsulates the first eutectic barrier layer 1414, the second adhesion layer 1418 encapsulates the conductive layer 1416, and the diffusion barrier layer 1420 encapsulates the second adhesion layer 1418.

Referring to both FIG. 14A and FIG. 14C, in the embodiment shown in FIG. 14A, the first eutectic barrier layer 1414 is positioned on one side of the polycrystalline ceramic core and the diffusion barrier layer 1420 encapsulates the polycrystalline ceramic core 1410. In the embodiment shown in FIG. 14C, the first eutectic barrier layer 1460 encapsulates the polycrystalline ceramic core 1410 and the diffusion barrier layer 1420 encapsulates the polycrystalline ceramic core 1410 as well.

As shown in the illustration of engineered substrate 1403 in FIG. 14D, the first eutectic barrier layer 1472 can be formed on both sides (i.e., the front side and the back side) as well as the peripheral sides of the first adhesion layer 1412, and the eutectic adhesion layer 1470 is coupled between the first eutectic barrier layer 1472 and the conductive layer 1416 on both sides (i.e., the front side and the back side). In other words, the embodiment shown in FIG. 14D is a combination of those shown in FIGS. 14B and 14C. One of ordinary skill in the art would recognize many variations, modifications, and alternatives.

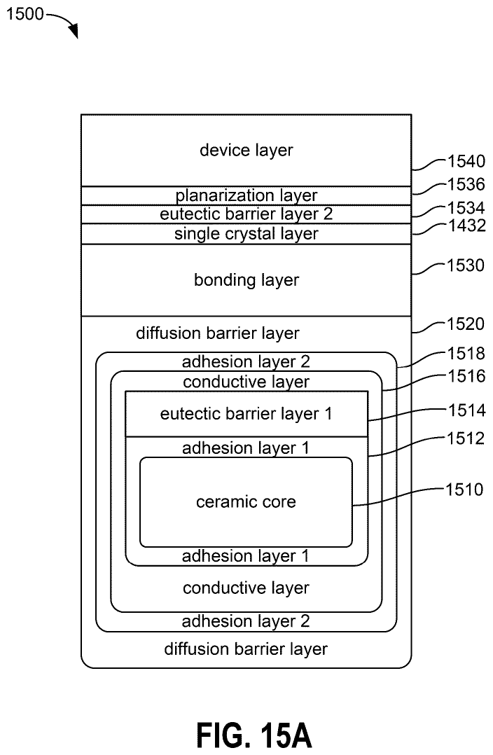

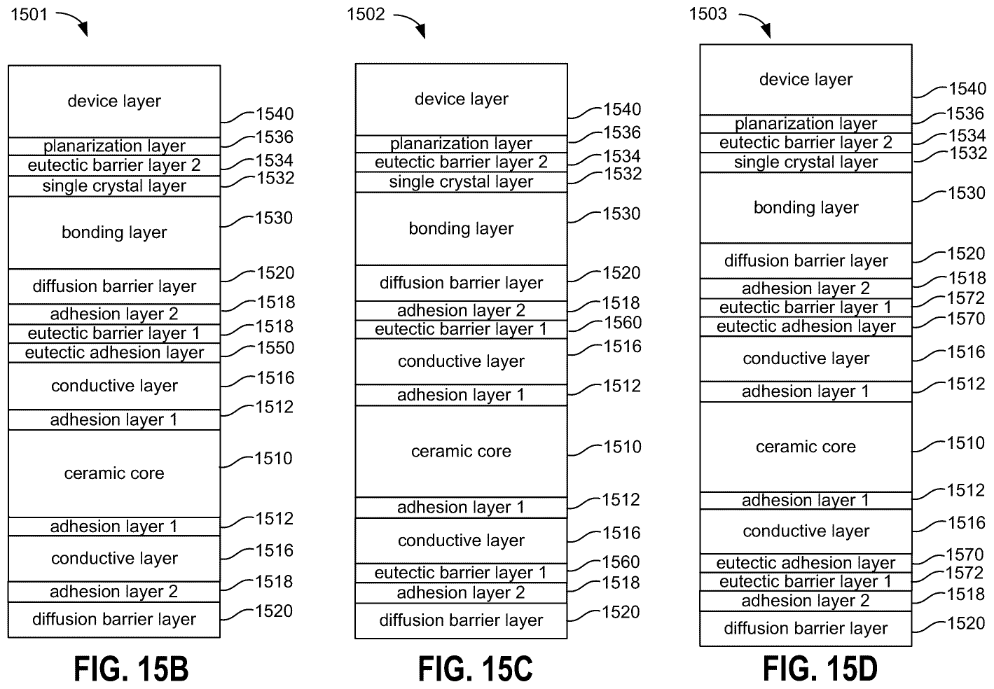

FIG. 15A is a simplified schematic diagram illustrating an engineered substrate structure according to an embodiment of the present invention. FIG. 15B is a simplified schematic diagram illustrating an engineered substrate structure according to another embodiment of the present invention. FIG. 15C is a simplified schematic diagram illustrating an engineered substrate structure according to another embodiment of the present invention. FIG. 15D is a simplified schematic diagram illustrating an engineered substrate structure according to another embodiment of the present invention. The engineered substrate illustrated in FIGS. 15A-15D share common elements with the engineered substrate illustrated in FIGS. 1 and 13A-13D and the discussion provided in relation to the engineered substrate illustrated in FIGS. 1 and 13A-13D is applicable to the engineered substrate illustrated in FIGS. 15A-15D as appropriate.

As shown in FIG. 15A, the engineered substrate 1500 includes a polycrystalline ceramic core 1510 and a first adhesion layer 1512 coupled to the polycrystalline ceramic core 1510. The engineered substrate 1500 also includes a first eutectic barrier layer 1514 coupled to the first adhesion layer 1512 and a conductive layer 1516 coupled to the first eutectic barrier layer 1514. The engineered substrate 1500 also includes a second adhesion layer 1518 coupled to the conductive layer 1516 and a diffusion barrier layer 1520 coupled to the second adhesion layer 1518. The engineered substrate 1500 also includes a bonding layer 1530 coupled to the diffusion barrier layer 1520 and a substantially single crystal layer 1532 coupled to the bonding layer 1530. The engineered substrate 1500 also includes a second eutectic barrier layer 1534 coupled to the single crystal layer 1532 and a planarization layer 1536 coupled to the second eutectic barrier layer 1534. The engineered substrate 1500 also includes a device layer 1540 coupled to the planarization layer 1536.

As illustrated in FIG. 15A, the first eutectic barrier layer 1514, the diffusion barrier layer 1520, and the second eutectic barrier layer 1534 can form a triple barrier layer structure, which collectively constrains or prevents both atomic or molecular diffusion and eutectic consumption/migration to the device layer 1540.

Because the first eutectic barrier layer 1514 is positioned between the polycrystalline ceramic core 1510 and the bonding layer 1530, even if the yttrium-based compound structure consumes a portion of the polycrystalline ceramic core 1510, the first adhesion layer 1512, and the conductive layer 1516, the resulting migration will not reach the bonding layer 1530. As a result, the bonding strength at the interface between the bonding layer 1530 and the substantially single crystalline layer 1532 is maintained.

As shown in the illustration of engineered substrate 1501 in FIG. 15B, a eutectic adhesion layer is coupled between the first eutectic barrier layer and the conductive layer. The eutectic adhesion layer can facilitate the coupling between the first eutectic barrier layer and the conductive layer.

As shown in the illustration of engineered substrate 1502 in FIG. 15C, the first eutectic barrier layer 1560 can be formed on both sides (i.e., the front side and the back side) as well as the peripheral sides of the conductive layer 1516. In one embodiment, the first adhesion layer 1512 encapsulates the polycrystalline ceramic core 1510, the conductive layer 1516 encapsulates the first adhesion layer 1512, the conductive layer 1516 encapsulates the first adhesion layer 1512, the first eutectic barrier layer 1560 encapsulates the conductive layer 1516, the second adhesion layer 1518 encapsulates the first eutectic barrier layer 1560, and the diffusion barrier layer 1520 encapsulates the second adhesion layer 1518.

As shown in the illustration of engineered substrate 1503 in FIG. 15D, the first eutectic barrier layer 1572 can be formed on both sides (i.e., the front side and the back side) as well as the peripheral sides of the conductive layer 1516, and the eutectic adhesion layer 1570 is coupled between the first eutectic barrier layer 1572 and the conductive layer on both sides (i.e., the front side and the back side). In other words, the embodiment shown in FIG. 15D is a combination of those shown in FIGS. 15B and 15C. One of ordinary skill in the art would recognize many variations, modifications, and alternatives.

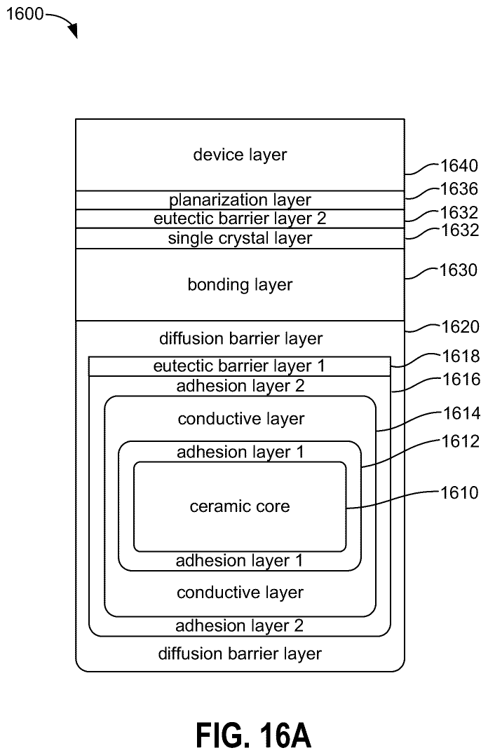

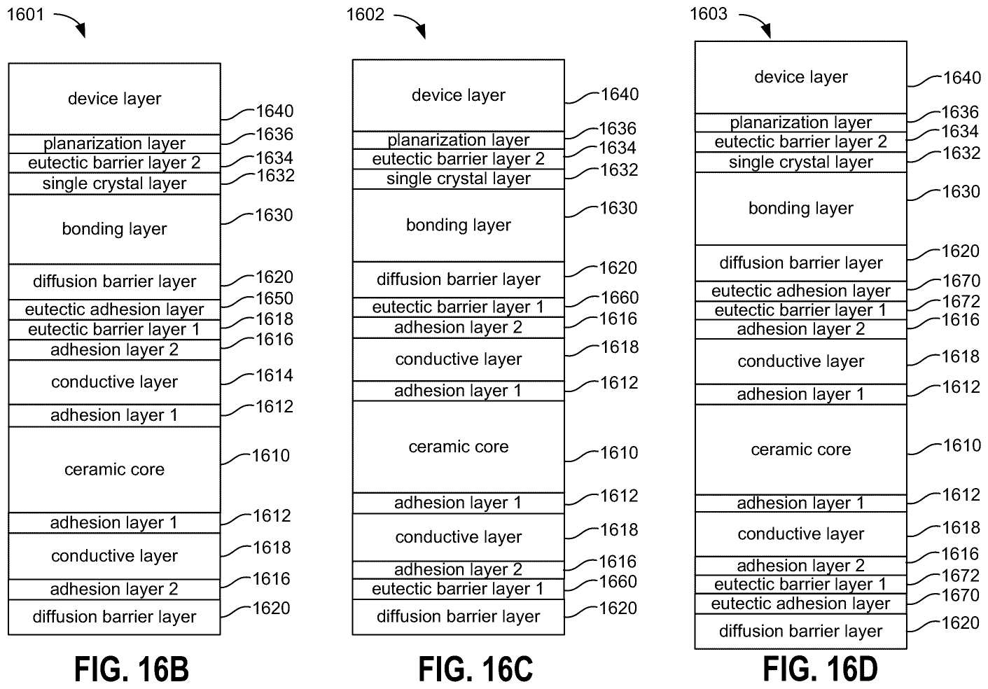

FIG. 16A is a simplified schematic diagram illustrating an engineered substrate structure according to an embodiment of the present invention. FIG. 16B is a simplified schematic diagram illustrating an engineered substrate structure according to another embodiment of the present invention. FIG. 16C is a simplified schematic diagram illustrating an engineered substrate structure according to another embodiment of the present invention. FIG. 16D is a simplified schematic diagram illustrating an engineered substrate structure according to another embodiment of the present invention. The engineered substrate illustrated in FIGS. 16A-16D share common elements with the engineered substrate illustrated in FIGS. 1 and 13A-13D and the discussion provided in relation to the engineered substrate illustrated in FIGS. 1 and 13A-13D is applicable to the engineered substrate illustrated in FIGS. 16A-16D as appropriate.

As shown in FIG. 16A, the engineered substrate 1600 includes a polycrystalline ceramic core 1610 and a first adhesion layer 1612 coupled to the polycrystalline ceramic core 1610. The engineered substrate 1600 also includes a conductive layer 1614 coupled to the first adhesion layer 1612 and a second adhesion layer 1616 coupled to the conductive layer 1614. The engineered substrate 1600 also includes a first eutectic barrier layer 1618 coupled to the second adhesion layer 1616 and a diffusion barrier layer 1620 coupled to the first eutectic barrier layer 1618. The engineered substrate 1600 also includes a bonding layer 1630 coupled to the diffusion barrier layer 1620 and a substantially single crystal layer 1632 coupled to the bonding layer 1630. The engineered substrate 1600 also includes a second eutectic barrier layer 1634 coupled to the single crystal layer 1600 and a planarization layer 1636 coupled to the second eutectic barrier layer 1634. The engineered substrate 1600 also includes a device layer 1640 coupled to the planarization layer 1636.

As shown in the illustration of engineered substrate 1601 in FIG. 16B, a eutectic adhesion layer 1650 is coupled between the first eutectic barrier layer 1618 and the diffusion barrier layer 1620. The eutectic adhesion layer 1650 can facilitate the coupling between the first eutectic barrier layer 1618 and the diffusion barrier layer 1620.

As shown in the illustration of engineered substrate 1602 in FIG. 16C, the first eutectic barrier layer 1660 can be formed on both sides (i.e., the front side and the back side) as well as the peripheral sides of the second adhesion layer 1616. In one embodiment, the first adhesion layer 1612 encapsulates the polycrystalline ceramic core 1610, the conductive layer 1614 encapsulates the first adhesion layer 1612, the second adhesion layer 1616 encapsulates the conductive layer 1614, the first eutectic barrier layer 1660 encapsulates the second adhesion layer 1616, and the diffusion barrier layer 1620 encapsulates the first eutectic barrier layer 1660.

As shown in the illustration of engineered substrate 1603 in FIG. 16D, the first eutectic barrier layer 1672 can be formed on both sides (i.e., the front side and the back side) as well as the peripheral sides of the second adhesion layer 1616, and the eutectic adhesion layer 1670 is coupled between the first eutectic barrier layer 1672 and the diffusion barrier 1620 layer on both sides (i.e., the front side and the back side). In other words, the embodiment shown in FIG. 16D is a combination of those shown in FIGS. 16B and 16C. One of ordinary skill in the art would recognize many variations, modifications, and alternatives.

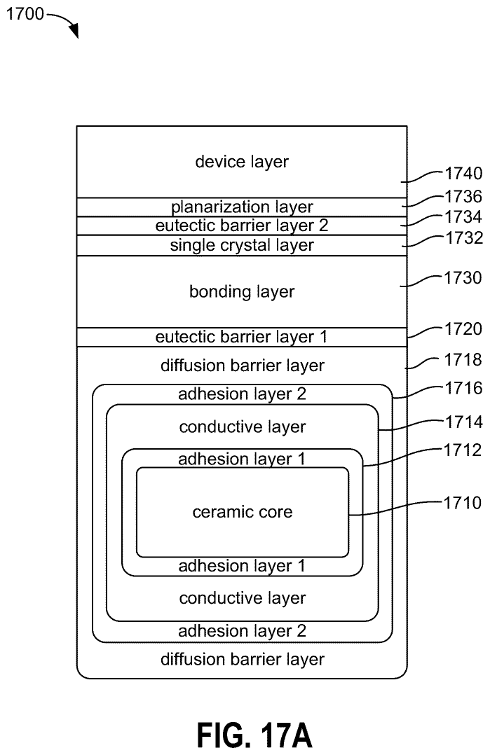

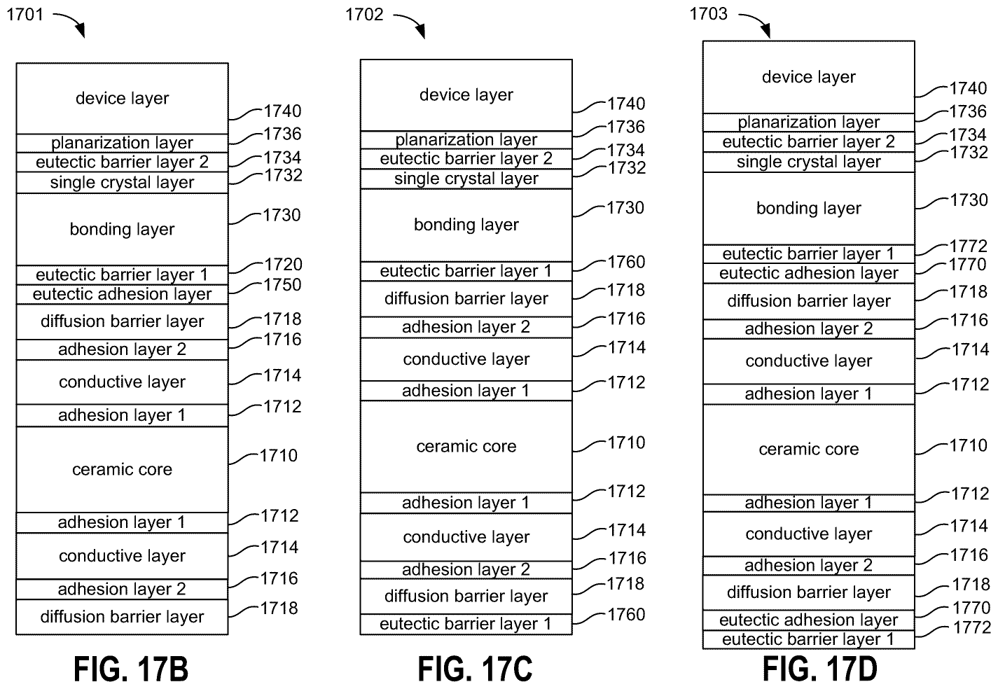

It should be noted that in the embodiments shown in FIGS. 13A-13D, 14A-14D, 15A-15D, and 16A-16D, the first eutectic barrier layer is positioned closer to the polycrystalline ceramic core than the diffusion barrier layer. In contrast, as will be discussed below, the embodiments shown in FIGS. 17A-17D differ in that the diffusion barrier layer is positioned closer to the polycrystalline ceramic core than the first eutectic barrier layer.

FIG. 17A is a simplified schematic diagram illustrating an engineered substrate structure according to an embodiment of the present invention. FIG. 17B is a simplified schematic diagram illustrating an engineered substrate structure according to another embodiment of the present invention. FIG. 17C is a simplified schematic diagram illustrating an engineered substrate structure according to another embodiment of the present invention. FIG. 17D is a simplified schematic diagram illustrating an engineered substrate structure according to another embodiment of the present invention. The engineered substrate illustrated in FIGS. 17A-17D share common elements with the engineered substrate illustrated in FIGS. 1 and 13A-13D and the discussion provided in relation to the engineered substrate illustrated in FIGS. 1 and 13A-13D is applicable to the engineered substrate illustrated in FIGS. 17A-17D as appropriate.

As shown in FIG. 17A, the engineered substrate 1700 includes a polycrystalline ceramic core 1710 and a first adhesion layer 1712 coupled to the polycrystalline ceramic core 1720. The engineered substrate 1700 also includes a conductive layer 1714 coupled to the first adhesion layer 1712 and a second adhesion layer 1716 coupled to the conductive layer 1714. The engineered substrate 1700 also includes a diffusion barrier layer 1718 coupled to the second adhesion layer 1716 and a first eutectic barrier layer 1720 coupled to the diffusion barrier layer 1718. The engineered substrate 1700 also includes bonding layer 1730 coupled to the first eutectic barrier layer 1720 and a substantially single crystal 1732 coupled to the bonding layer 1730. The engineered substrate 1700 also includes a second eutectic barrier layer 1734 coupled to the single crystal layer 1732 and a planarization layer 1736 coupled to the second eutectic barrier layer 1734. The engineered substrate 1700 also includes a device layer 1740 coupled to the planarization layer 1736.

As shown in the illustration of engineered substrate 1701 in FIG. 17B, a eutectic adhesion layer 1750 is coupled between the first eutectic barrier layer 1720 and the diffusion barrier layer 1718. The eutectic adhesion layer 1750 can facilitate the coupling between the first eutectic barrier layer 1720 and the diffusion barrier layer 1718.

As shown in the illustration of engineered substrate 1702 in FIG. 17C, the first eutectic barrier layer 1760 can be formed on both sides (i.e., the front side and the back side) as well as the peripheral sides of the diffusion barrier layer. In one embodiment, the first adhesion layer 1712 encapsulates the polycrystalline ceramic core 1710, the conductive layer 1714 encapsulates the first adhesion layer 1712, the second adhesion layer 1716 encapsulates the conductive layer 1714, the diffusion barrier layer 1718 encapsulates the second adhesion layer, 1716 and the first eutectic barrier layer 1720 encapsulates the diffusion barrier layer 1780.

As shown in the illustration of engineered substrate 1703 in FIG. 17D, the first eutectic barrier layer 1772 can be formed on both sides (i.e., the front side and the back side) as well as the peripheral sides of the diffusion barrier layer 1720, and the eutectic adhesion layer 1770 is coupled between the first eutectic barrier layer 1772 and the diffusion barrier layer 1720 on both sides (i.e., the front side and the back side). In other words, the embodiment shown in FIG. 17D is a combination of those shown in FIGS. 17B and 17C. One of ordinary skill in the art would recognize many variations, modifications, and alternatives.

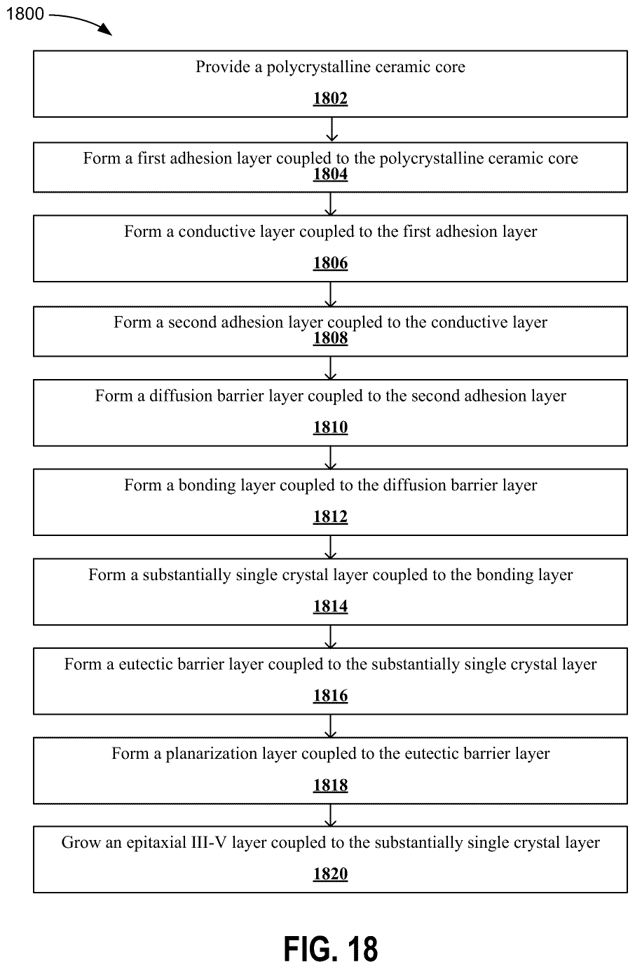

FIG. 18 is a diagram illustrating a simplified flowchart illustrating a method of fabricating an engineered substrate structure according to an embodiment of the present invention. The method 1800 includes providing a polycrystalline ceramic core (1802). The method 1800 also includes forming a first adhesion layer coupled to the polycrystalline ceramic core (1804) layer and forming a conductive layer coupled to the first adhesion layer (1806). The method 1800 also includes forming a second adhesion layer coupled to the conductive layer (1808) and forming a diffusion barrier layer coupled to the second adhesion layer (1810). The method 1800 also includes forming a bonding layer coupled to the diffusion barrier layer (1812) and forming a substantially single crystal layer coupled to the bonding layer (1814). The method 1800 also includes forming a eutectic barrier layer coupled to the substantially single crystal layer (1816) and forming a planarization layer coupled to the eutectic barrier layer (1818). The method 1800 may also include growing an epitaxial III-V layer coupled to the substantially single crystal layer (1820).

It should be appreciated that the specific steps illustrated in FIG. 18 provide a particular method of fabricating a multi-core engineered substrate structure according to an embodiment of the present invention. Other sequences of steps may also be performed according to alternative embodiments. For example, alternative embodiments of the present invention may perform the steps outlined above in a different order. Moreover, the individual steps illustrated in FIG. 18 may include multiple sub-steps that may be performed in various sequences as appropriate to the individual step. Furthermore, additional steps may be added or removed depending on the particular applications. One of ordinary skill in the art would recognize many variations, modifications, and alternatives.

The method 1800 can be used to fabricate the engineered substrate shown in FIG. 12. Similar methods can be used to fabricate the engineered substrates shown in FIGS. 13A-13D, 14A-14D, 15A-15D, 16A-16D, and 17A-17D. One of ordinary skill in the art would recognize many variations, modifications, and alternatives.

According to an embodiment of the present invention, an engineered substrate is provided. The engineered substrate includes a polycrystalline ceramic core, a eutectic barrier layer coupled to the polycrystalline ceramic core, a first adhesion layer coupled to the eutectic barrier layer, a conductive layer coupled to the first adhesion layer, a second adhesion layer coupled to the conductive layer, a diffusion barrier layer coupled to the second adhesion layer, a bonding layer coupled to the diffusion barrier layer, a substantially single crystal layer coupled to the bonding layer, and an epitaxial III-V layer coupled to the substantially single crystal layer.

According to another embodiment of the present invention, a method is provided. The method includes providing a polycrystalline ceramic core, forming a eutectic barrier layer coupled to the polycrystalline ceramic core, forming a first adhesion layer coupled to the eutectic barrier layer, forming a conductive layer coupled to the first adhesion layer, forming a second adhesion layer coupled to the conductive layer, forming a diffusion barrier layer coupled to the second adhesion layer, forming a bonding layer coupled to the diffusion barrier layer, forming a substantially single crystal layer coupled to the bonding layer, and growing an epitaxial III-V layer coupled to the substantially single crystal layer.

According to another embodiment of the present invention, an engineered substrate is provided. The engineered substrate includes a polycrystalline ceramic core, a first adhesion layer coupled to the polycrystalline ceramic core, a eutectic barrier layer coupled to the first adhesion layer, a conductive layer coupled to the eutectic barrier layer, a second adhesion layer coupled to the conductive layer, a diffusion barrier layer coupled to the second adhesion layer, a bonding layer coupled to the diffusion barrier layer, a substantially single crystal layer coupled to the bonding layer, and an epitaxial III-V layer coupled to the substantially single crystal layer.

According to yet another embodiment of the present invention, a method is provided. The method includes providing a polycrystalline ceramic core, forming a first adhesion layer coupled to the polycrystalline ceramic core, forming a eutectic barrier layer coupled to the first adhesion layer, forming a conductive layer coupled to the eutectic barrier layer, forming a second adhesion layer coupled to the conductive layer, forming a diffusion barrier layer coupled to the second adhesion layer, forming a bonding layer coupled to the diffusion barrier layer, forming a substantially single crystal layer coupled to the bonding layer, and growing an epitaxial III-V layer coupled to the substantially single crystal layer.

According to a particular embodiment of the present invention, an engineered substrate is provided. The engineered substrate includes a polycrystalline ceramic core, a first adhesion layer coupled to the polycrystalline ceramic core, a conductive layer coupled to the first adhesion layer, a eutectic barrier layer coupled to the conductive layer, a second adhesion layer coupled to the eutectic barrier layer, a diffusion barrier layer coupled to the second adhesion layer, a bonding layer coupled to the diffusion barrier layer, a substantially single crystal layer coupled to the bonding layer, and an epitaxial III-V layer coupled to the substantially single crystal layer.

According to another particular embodiment of the present invention, a method is provided. The method includes providing a polycrystalline ceramic core, forming a first adhesion layer coupled to the polycrystalline ceramic core, forming a conductive layer coupled to the first adhesion layer, forming a eutectic barrier layer coupled to the conductive layer, forming a second adhesion layer coupled to the eutectic barrier layer, forming a diffusion barrier layer coupled to the second adhesion layer, forming a bonding layer coupled to the diffusion barrier layer, forming a substantially single crystal layer coupled to the bonding layer, and growing an epitaxial III-V layer coupled to the substantially single crystal layer.

According to a specific embodiment of the present invention, an engineered substrate is provided. The engineered substrate includes a polycrystalline ceramic core, a first adhesion layer coupled to the polycrystalline ceramic core, a conductive layer coupled to the first adhesion layer, a second adhesion layer coupled to the conductive layer, a eutectic barrier layer coupled to the second adhesion layer, a diffusion barrier layer coupled to the eutectic barrier layer, a bonding layer coupled to the diffusion barrier layer, a substantially single crystal layer coupled to the bonding layer, and an epitaxial III-V layer coupled to the substantially single crystal layer.

According to another specific embodiment of the present invention, a method is provided. The method includes providing a polycrystalline ceramic core, forming a first adhesion layer coupled to the polycrystalline ceramic core, forming a conductive layer coupled to the first adhesion layer, forming a second adhesion layer coupled to the conductive layer, forming a eutectic barrier layer coupled to the second adhesion layer, forming a diffusion barrier layer coupled to the eutectic barrier layer, forming a bonding layer coupled to the diffusion barrier layer, forming a substantially single crystal layer coupled to the bonding layer, and growing an epitaxial III-V layer coupled to the substantially single crystal layer.

According to an embodiment of the present invention, an engineered substrate is provided. The engineered substrate includes a polycrystalline ceramic core, a first adhesion layer coupled to the polycrystalline ceramic core, a conductive layer coupled to the first adhesion layer, a second adhesion layer coupled to the conductive layer, a diffusion barrier layer coupled to the second adhesion layer, a eutectic barrier layer coupled to the diffusion barrier layer, a bonding layer coupled to the eutectic barrier layer, a substantially single crystal layer coupled to the bonding layer, and an epitaxial III-V layer coupled to the substantially single crystal layer.

According to another embodiment of the present invention, a method is provided. The method includes providing a polycrystalline ceramic core, forming a first adhesion layer coupled to the polycrystalline ceramic core, forming a conductive layer coupled to the first adhesion layer, forming a second adhesion layer coupled to the conductive layer, forming a diffusion barrier layer coupled to the second adhesion layer, forming a eutectic barrier layer coupled to the diffusion barrier layer, forming a bonding layer coupled to the eutectic barrier layer, forming a substantially single crystal layer coupled to the bonding layer, and growing an epitaxial III-V layer coupled to the substantially single crystal layer.

According to a specific embodiment of the present invention, an engineered substrate is provided. The engineered substrate includes a polycrystalline ceramic core, a first adhesion layer coupled to the polycrystalline ceramic core, a conductive layer coupled to the first adhesion layer, a second adhesion layer coupled to the conductive layer, a diffusion barrier layer coupled to the second adhesion layer, a bonding layer coupled to the diffusion barrier layer, and a substantially single crystal layer coupled to the bonding layer. A first region of the engineered substrate includes an epitaxial III-V layer coupled to the substantially single crystal layer. A second region of the engineered substrate includes a eutectic barrier layer coupled to the bonding layer, a planarization layer coupled to the eutectic barrier layer, and an epitaxial III-V layer coupled to the planarization layer.

The substantially single crystal layer can include a perforated substantially single crystal structure exposing the bonding layer. The substantially single crystal layer can be discontinuous. The eutectic barrier layer can include aluminum nitride or have a thickness of about 100 Å. The engineered substrate can also include a second eutectic barrier layer coupled to the polycrystalline ceramic core. The second eutectic barrier layer can encapsulate the polycrystalline ceramic core. The engineered substrate can further include a eutectic adhesion layer coupled to the second eutectic barrier layer. The epitaxial III-V layer can include an epitaxial gallium nitride layer. The first adhesion layer can include a first tetraethyl orthosilicate (TEOS) layer encapsulating the polycrystalline ceramic core, the conductive layer can include a polysilicon layer encapsulating the first TEOS layer, the second adhesion layer can include a second TEOS layer encapsulating the polysilicon layer, and the diffusion barrier layer can include a silicon nitride layer encapsulating the second TEOS layer.

According to another specific embodiment of the present invention, a method is provided. The method includes providing a polycrystalline ceramic core, forming a first adhesion layer coupled to the polycrystalline ceramic core, forming a conductive layer coupled to the first adhesion layer, forming a second adhesion layer coupled to the conductive layer, forming a diffusion barrier layer coupled to the second adhesion layer, forming a bonding layer coupled to the diffusion barrier layer, forming a substantially single crystal layer coupled to the bonding layer, growing, on a first region, an epitaxial III-V layer coupled to the substantially single crystal layer; and forming, on a second region, a eutectic barrier layer coupled to the bonding layer, forming, on the second region, a planarization layer coupled to the eutectic barrier layer, and growing, on the second region, the epitaxial III-V layer coupled to the planarization layer.

The substantially single crystal layer can include a perforated substantially single crystal structure exposing the bonding layer. The substantially single crystal layer can be discontinuous. The eutectic barrier layer can include aluminum nitride or have a thickness of about 100 Å. The method can further include forming a second eutectic barrier layer coupled to the polycrystalline ceramic core. The second eutectic barrier layer can encapsulate the polycrystalline ceramic core. The method can also include forming a eutectic adhesion layer coupled to the second eutectic barrier layer. The epitaxial III-V layer can include an epitaxial gallium nitride layer. The first adhesion layer can include a first tetraethyl orthosilicate (TEOS) layer can encapsulate the polycrystalline ceramic core, the conductive layer can include a polysilicon layer can encapsulate the first TEOS layer, the second adhesion layer can include a second TEOS layer can encapsulate the polysilicon layer, and the diffusion barrier layer can include a silicon nitride layer can encapsulate the second TEOS layer.

According to an embodiment of the present invention, an engineered substrate is provided. The engineered substrate includes a polycrystalline ceramic core; a eutectic barrier layer coupled to the polycrystalline ceramic core; a first adhesion layer coupled to the eutectic barrier layer; a conductive layer coupled to the first adhesion layer; a second adhesion layer coupled to the conductive layer; a diffusion barrier layer coupled to the second adhesion layer; a bonding layer coupled to the diffusion barrier layer; a substantially single crystal layer coupled to the bonding layer; and an epitaxial III-V layer coupled to the substantially single crystal layer.

The engineered substrate can further include a eutectic adhesion layer disposed between the polycrystalline ceramic core and the eutectic barrier layer. The eutectic barrier layer can encapsulate the polycrystalline ceramic core. The engineered substrate can further include a eutectic adhesion layer disposed between the polycrystalline ceramic core and the eutectic barrier layer, wherein: the eutectic barrier layer encapsulates the eutectic adhesion layer; and the eutectic adhesion layer encapsulates the polycrystalline ceramic core. The polycrystalline ceramic core can include aluminum nitride or silicon carbide. The eutectic barrier layer can include aluminum nitride. The eutectic barrier layer can include an AlON layer, Al₂O₃, TaN, or TiN. The engineered substrate can further include an epitaxial device layer coupled to the epitaxial III-V layer, wherein the coefficient of thermal expansion of the polycrystalline ceramic core and the epitaxial device layer are equal. The first adhesion layer can encapsulate the eutectic barrier layer; the conductive layer can encapsulate the first adhesion layer; the second adhesion layer can encapsulate the conductive layer; and the diffusion barrier layer can encapsulate the second adhesion layer. The conductive layer can include a polysilicon layer. The bonding layer can include a silicon oxide layer. The substantially single crystal layer can include a single crystal silicon layer. The epitaxial III-V layer can include an epitaxial gallium nitride layer.

According to another embodiment of the present invention, a method is provided. The method includes providing a polycrystalline ceramic core; forming a eutectic barrier layer coupled to the polycrystalline ceramic core; forming a first adhesion layer coupled to the eutectic barrier layer; forming a conductive layer coupled to the first adhesion layer; forming a second adhesion layer coupled to the conductive layer; forming a diffusion barrier layer coupled to the second adhesion layer; forming a bonding layer coupled to the diffusion barrier layer; forming a substantially single crystal layer coupled to the bonding layer; and growing an epitaxial III-V layer coupled to the substantially single crystal layer. The method can also include forming a eutectic adhesion layer disposed between the polycrystalline ceramic core and the eutectic barrier layer. The eutectic barrier layer can encapsulate the polycrystalline ceramic core. The method can further include forming a eutectic adhesion layer disposed between the polycrystalline ceramic core and the eutectic barrier layer, wherein: the eutectic barrier layer encapsulates the eutectic adhesion layer; and the eutectic adhesion layer encapsulates the polycrystalline ceramic core. The polycrystalline ceramic core can include aluminum nitride or silicon carbide. The eutectic barrier layer can include aluminum nitride. The eutectic barrier layer can include an AlON layer, Al₂O₃, TaN, or TiN. The method can also include forming an epitaxial device layer coupled to the epitaxial III-V layer, wherein the coefficient of thermal expansion of the polycrystalline ceramic core and the epitaxial device layer are equal. The eutectic barrier layer can include a continuous film. The first adhesion layer can encapsulate the eutectic barrier layer; the conductive layer can encapsulate the first adhesion layer; the second adhesion layer can encapsulate the conductive layer; and the diffusion barrier layer can encapsulate the second adhesion layer. The conductive layer can include a polysilicon layer. The bonding layer can include a silicon oxide layer. The substantially single crystal layer can include a single crystal silicon layer. The epitaxial III-V layer can include an epitaxial gallium nitride layer.

Various examples of the present disclosure are provided below. As used below, any reference to a series of examples is to be understood as a reference to each of those examples disjunctively (e.g., “Examples 1-4” is to be understood as “Examples 1, 2, 3, or 4”).

Example 1 is an engineered substrate comprising: a polycrystalline ceramic core; a first adhesion layer coupled to the polycrystalline ceramic core; a conductive layer coupled to the first adhesion layer; a second adhesion layer coupled to the conductive layer; a diffusion barrier layer coupled to the second adhesion layer; a bonding layer coupled to the diffusion barrier layer; a substantially single crystal layer coupled to the bonding layer; a first region of the engineered substrate including: an epitaxial III-V layer coupled to the substantially single crystal layer; a second region of the engineered substrate including: a eutectic barrier layer coupled to the bonding layer; a planarization layer coupled to the eutectic barrier layer; and an epitaxial III-V layer coupled to the planarization layer.

Example 2 is the engineered substrate of example 1 wherein the substantially single crystal layer comprises a perforated substantially single crystal structure exposing the bonding layer.

Example 3 is the engineered substrate of example(s) 1-2 wherein the substantially single crystal layer is discontinuous.

Example 4 is the engineered substrate of example(s) 1-3 wherein the eutectic barrier layer comprises aluminum nitride.

Example 5 is the engineered substrate of example(s) 1-4 wherein the eutectic barrier layer has a thickness of about 100 Å.

Example 6 is the engineered substrate of example(s) 1-5 further comprising a second eutectic barrier layer coupled to the polycrystalline ceramic core.

Example 7 is the engineered substrate of example(s) 1-6 wherein the second eutectic barrier layer encapsulates the polycrystalline ceramic core.

Example 8 is the engineered substrate of example(s) 1-7 further comprising a eutectic adhesion layer coupled to the second eutectic barrier layer.

Example 9 is the engineered substrate of example(s) 1-8 wherein the epitaxial III-V layer comprises an epitaxial gallium nitride layer.

Example 10 is the engineered substrate of example(s) 1-9 wherein: the first adhesion layer comprises a first tetraethyl orthosilicate (TEOS) layer encapsulating the polycrystalline ceramic core; the conductive layer comprises a polysilicon layer encapsulating the first TEOS layer; the second adhesion layer comprises a second TEOS layer encapsulating the polysilicon layer; and the diffusion barrier layer comprises a silicon nitride layer encapsulating the second TEOS layer.

Example 11 is a method comprising: providing a polycrystalline ceramic core; forming a first adhesion layer coupled to the polycrystalline ceramic core; forming a conductive layer coupled to the first adhesion layer; forming a second adhesion layer coupled to the conductive layer; forming a diffusion barrier layer coupled to the second adhesion layer; forming a bonding layer coupled to the diffusion barrier layer; forming a substantially single crystal layer coupled to the bonding layer; growing, on a first region, an epitaxial III-V layer coupled to the substantially single crystal layer; and forming, on a second region, a eutectic barrier layer coupled to the bonding layer; forming, on the second region, a planarization layer coupled to the eutectic barrier layer; and growing, on the second region, the epitaxial III-V layer coupled to the planarization layer.

Example 12 is the method of example 11 wherein the substantially single crystal layer comprises a perforated substantially single crystal structure exposing the bonding layer.

Example 13 is the method of example(s) 11-12 wherein the substantially single crystal layer is discontinuous.

Example 14 is the method of example(s) 11-13 wherein the eutectic barrier layer comprises aluminum nitride.

Example 15 is the method of example(s) 11-14 wherein the eutectic barrier layer has a thickness of about 100 Å.

Example 16 is the method of example(s) 11-15 further comprising forming a second eutectic barrier layer coupled to the polycrystalline ceramic core.

Example 17 is the method of example(s) 11-16 wherein the second eutectic barrier layer encapsulates the polycrystalline ceramic core.

Example 18 is the method of example(s) 11-17 further comprising forming a eutectic adhesion layer coupled to the second eutectic barrier layer.

Example 19 is the method of example(s) 11-18 wherein the epitaxial III-V layer comprises an epitaxial gallium nitride layer.

Example 20 is the method of example(s) 11-20 wherein: the first adhesion layer comprises a first tetraethyl orthosilicate (TEOS) layer encapsulating the polycrystalline ceramic core; the conductive layer comprises a polysilicon layer encapsulating the first TEOS layer; the second adhesion layer comprises a second TEOS layer encapsulating the polysilicon layer; and the diffusion barrier layer comprises a silicon nitride layer encapsulating the second TEOS layer.

It is also understood that the examples and embodiments described herein are for illustrative purposes only and that various modifications or changes in light thereof will be suggested to persons skilled in the art and are to be included within the spirit and purview of this application and scope of the appended claims.

1. An engineered substrate comprising:
a polycrystalline ceramic core;
a first adhesion layer coupled to the polycrystalline ceramic core;
a conductive layer coupled to the first adhesion layer;
a second adhesion layer coupled to the conductive layer;
a diffusion barrier layer coupled to the second adhesion layer;
a bonding layer coupled to the diffusion barrier layer;
a substantially single crystal layer coupled to the bonding layer;
a first region of the engineered substrate including:
an epitaxial III-V layer coupled to the substantially single crystal layer;
a second region of the engineered substrate including:
a eutectic barrier layer coupled to the bonding layer;
a planarization layer coupled to the eutectic barrier layer; and
an epitaxial III-V layer coupled to the planarization layer.

2. The engineered substrate of claim 1 wherein the substantially single crystal layer comprises a perforated substantially single crystal structure exposing the bonding layer.

3. The engineered substrate of claim 1 wherein the substantially single crystal layer is discontinuous.

4. The engineered substrate of claim 1 wherein the eutectic barrier layer comprises aluminum nitride.

5. The engineered substrate of claim 1 wherein the eutectic barrier layer has a thickness of about 100 Å.

6. The engineered substrate of claim 1 further comprising a second eutectic barrier layer coupled to the polycrystalline ceramic core.

7. The engineered substrate of claim 6 wherein the second eutectic barrier layer encapsulates the polycrystalline ceramic core.

8. The engineered substrate of claim 6 further comprising a eutectic adhesion layer coupled to the second eutectic barrier layer.

9. The engineered substrate of claim 1 wherein the epitaxial III-V layer comprises an epitaxial gallium nitride layer.

10. The engineered substrate of claim 1 wherein:
the first adhesion layer comprises a first tetraethyl orthosilicate (TEOS) layer encapsulating the polycrystalline ceramic core;
the conductive layer comprises a polysilicon layer encapsulating the first TEOS layer;
the second adhesion layer comprises a second TEOS layer encapsulating the polysilicon layer; and
the diffusion barrier layer comprises a silicon nitride layer encapsulating the second TEOS layer.

11. A method comprising:
providing a polycrystalline ceramic core;
forming a first adhesion layer coupled to the polycrystalline ceramic core;
forming a conductive layer coupled to the first adhesion layer;
forming a second adhesion layer coupled to the conductive layer;
forming a diffusion barrier layer coupled to the second adhesion layer;
forming a bonding layer coupled to the diffusion barrier layer;
forming a substantially single crystal layer coupled to the bonding layer;
growing, on a first region, an epitaxial III-V layer coupled to the substantially single crystal layer; and
forming, on a second region, a eutectic barrier layer coupled to the bonding layer;
forming, on the second region, a planarization layer coupled to the eutectic barrier layer;
and growing, on the second region, the epitaxial III-V layer coupled to the planarization layer.

12. The method of claim 11 wherein the substantially single crystal layer comprises a perforated substantially single crystal structure exposing the bonding layer.

13. The method of claim 11 wherein the substantially single crystal layer is discontinuous.

14. The method of claim 11 wherein the eutectic barrier layer comprises aluminum nitride.

15. The method of claim 11 wherein the eutectic barrier layer has a thickness of about 100 Å.

16. The method of claim 11 further comprising forming a second eutectic barrier layer coupled to the polycrystalline ceramic core.

17. The method of claim 16 wherein the second eutectic barrier layer encapsulates the polycrystalline ceramic core.

18. The method of claim 16 further comprising forming a eutectic adhesion layer coupled to the second eutectic barrier layer.

19. The method of claim 11 wherein the epitaxial III-V layer comprises an epitaxial gallium nitride layer.

20. The method of claim 11 wherein:
the first adhesion layer comprises a first tetraethyl orthosilicate (TEOS) layer encapsulating the polycrystalline ceramic core;
the conductive layer comprises a polysilicon layer encapsulating the first TEOS layer;
the second adhesion layer comprises a second TEOS layer encapsulating the polysilicon layer; and
the diffusion barrier layer comprises a silicon nitride layer encapsulating the second TEOS layer.
